(19) United States
(12) Patent Application Publication
(10) Pub. No.: US 2016/0188771 A1
(43) Pub. Date: Jun. 30, 2016

(54) SYSTEM FOR OPTIMIZATION OF METHOD FOR DETERMINING MATERIAL PROPERTIES AT FINDING MATERIALS HAVING DEFINED PROPERTIES AND OPTIMIZATION OF METHOD FOR DETERMINING MATERIAL PROPERTIES AT FINDING MATERIALS HAVING DEFINED PROPERTIES

(71) Applicant: Wladyslaw Wlodarczyk IGLOO, Nowy Wisnicz (PL)

(72) Inventor: Rafal Michalski, Krakow (PL)

(73) Assignee: Wladyslaw Wlodarczyk IGLOO, Nowy Wisnicz (PL)

(21) Appl. No.: 14/981,913

(22) Filed: Dec. 29, 2015

(30) Foreign Application Priority Data
Dec. 31, 2014 (EP) 14461609.1

(51) Int. Cl. G06F 17/50; G01R 29/08; G06F 17/18

(52) U.S. Cl. CPC G06F 17/5009; G06F 17/18; G01R 29/0892

(57) ABSTRACT

In a system for optimization of method for determining material properties when searching for materials having defined properties, comprising a computing unit with a processor and a device for presentation of data and calculation results, and with access to data on materials, and a testing unit carrying out tests on real materials and communicating with the computing unit, the computing unit having a module (60) for construction of a model of an ideal material, which comprises a module (64) for calculation of complete sets of pairs of the energy eigenvalues Eⁱ (i=1 . . . n) and eigenfunctions being linear combinations of basis vectors, and a module (68) for calculation of courses of temperature dependencies of free energy, internal energy, entropy, magnetic susceptibility, calculated for a field applied along (x and z) or (x, y and z) directions, and Schottky specific heat in order to determine the calorimetric, electron and magnetic properties of a material containing ions in the defined environment of the Crystal Electric Field (CEF).

### CROSS-REFERENCE TO RELATED APPLICATIONS

Pursuant to 35 U.S.C. 119 and the Paris Convention Treaty this application claims the benefit of European Patent Application No. EP14461609.1 filed on Dec. 31, 2014, the contents of which are incorporated herein by reference.

### BACKGROUND OF THE INVENTION

1. Field of the Invention

Technical concept presented herein relates to a system for optimization of a method for determining material properties at finding materials or when searching for materials having defined properties and optimization of the method for determining material properties at finding materials when searching for materials having defined properties, particularly materials containing elements chosen from Periodic Table and having at least one kind of ions with electron subshell containing number of electrons starting from 1 to value adequate to situation called closed electron subshell (e.g. for subshell s=2, p=6, d=10 and f=14). This case, according to atomic physic and physical chemistry nominalism, is called unclosed atomic subshell s,p,d or f and is the object of simulation and a starting point of physical analysis of influence of existence such ions for bulk properties of materials containing them.

2. Description of the Related Art

Search for materials with defined properties is a long and expensive process, even in the era of advanced material technology and with modern research technique, using devices controlled by computers with high computing power. Currently, the properties of materials, such as mechanical, thermal or magnetic properties, are defined analysing samples made of a defined material. When it turns out, during the analysis, that the material has properties fulfilling the criteria defined by the designers, the step of finding materials with properties defined in the project ends. Examples of projects requiring materials with given properties may include a suspension bridge, a vehicle or even a semiconductor.

From publication No. CA2863843 A1 of the Patent Application titled “Apparatus and method for measuring properties of ferromagnetic material”, a device for measuring properties of an object made of ferromagnetic material is known.

From publication No. WO2014134655 A1 of the Patent Application titled “Estimating material properties”, an update of data on the concentration of iron in a bulk mine sample is known. The definition of properties of material is based on values of one or more parameters of the sample. After obtaining measurements concerning properties of a material, the processor of the processing unit decides on an update of values concerning the properties of the material, based on the measurements.

From publication No. WO2014150916 A1 of the Patent Application entitled “Systems and methods for improving direct numerical simulation of material properties from rock samples and determining uncertainty in the material properties”, a method for determination of Representative Elementary Volume based on one or more properties of material is known. The method consists in defining multiple test volumes, determining the value of the difference between neighbouring pairs of sample volumes and adopting the Representative Elementary Volume based on the value of the difference for every multiplicity of the tested volumes.

### SUMMARY OF THE INVENTION

It is an object of the present invention to provide optimisation of a method for determining material properties at finding materials or when searching for materials having defined properties, based particularly on the knowledge of Crystal Electric Field (CEF).

This objective is achieved in that during the optimisation a material containing ions of at least one element with unclosed electron shells is selected based on information available in the state of art. Next, at least one component element of chosen material is defined, then, an oxidation state of atoms of the component element being selected in the chosen material is determined to define their electron configuration, and next, for selected ions of the component element, after determining values of quantum numbers of an orbital magnetic moment L, a spin magnetic moment S and optionally a total magnetic moment J corresponding to a ground state of the selected ions, calculations are carried out to find a complete set of Crystal Electric Field (CEF) coefficients, defined by Stevens coefficients which define value of influence of electric multipoles interacting with unclosed electronic subshell of ion, having a form of B^{m}ₙ, expressed in energy units and defining an immediate charge environment of the selected ions in a crystal lattice by calculation of Stevens coefficients having the form of B^{m}ₙ, based on total energy operator (called Hamiltonian) defined by Hamiltonian matrix is generated, containing matrix components with elements of Stevens operators multiplied by the defined Stevens coefficients B^{m}ₙ (H_{CEF}=ΣB^{m}ₙO^{m}ₙ), and (x, y, z) or (x, z) components of operators of the magnetic field potential, projection operators of orbital magnetic moment, spin magnetic moment and total magnetic moment, and optionally components of operators of the spin-orbit coupling, and after carrying out operations on the matrix, a model of an ideal material containing the selected ions is created, the selected ions being spatially oriented identically and not interacting with each other, but interacting with external magnetic and electric fields, with a calculated structure of energy states together with their spectral properties, and being subjected to classical Boltzmann statistics, and having the directional (x, y, z) or (x, z) components of magnetic properties calculated, and based on the model of the ideal material, calorimetric, electron and magnetic properties are being defined in a form of temperature dependencies of material containing ions in the defined environment of the crystal field (CEF), while the properties of the ideal material are verified with properties of a real material, when the properties of the material obtained from calculations correspond to the properties of the material being searched for.

The values of quantum numbers of orbital magnetic moment L, spin magnetic moment S and optionally total magnetic moment J corresponding to the ground state of electron configuration of a selected ion may be determined based on Hund's rules.

Calculation of Stevens coefficients having the form of B^{m}ₙ may be carried out after choosing one of the calculation methods and defining the computation space, selecting a basis for calculations and determining the values of constants.

In a preferred embodiment of the invention, calculations of the Stevens coefficients having the form of B^{m}ₙ are carried out using Point Charge Model Approximation (PCM) or using an interactive three-dimensional (3D) visualisation of component multi-poles of the electric field and their superpositions defined as crystal field (CEF) or by a conversion of crystal field (CEF) coefficients (A^{m}ₙ→B^{m}ₙ) from known results of other calculations for systems isostructural with the one being calculated, but containing other ions.

The results of calculations of the Stevens coefficients having the of form B^{m}ₙ may be harmonised by comparing the obtained results using Point Charge Model Approximation (PCM) or an interactive visualisation of the crystal field (CEF) in 3D, or by a conversion of crystal field (CEF) coefficients (A^{m}ₙ→B^{m}ₙ) from results of other calculations for systems isostructural with the one being calculated, but containing other ions.

All operations leading to the calculation of the structure of states of the selected ions in the defined environment in the crystal lattice may be carried out after choosing the computation space from a vector space spanned across a body of real numbers and space spanned across a body of complex numbers and choosing a basis for construction of the Hamiltonian matrix, or the total energy operator.

It may be anticipated that after choosing the space of real numbers and carrying out the calculations in the |L,S,J,J_{z}> basis, while generating the matrix containing the products of the matrix elements of Stevens operators and defined Stevens coefficients (B^{m}ₙ, O^{m}ₙ), and operators of directional components (x, z) of the magnetic field, at first, an empty matrix is created with rows and columns numbered with values of |J_{z}>, the matrix being filled with products of the matrix elements of Stevens operators and defined Stevens coefficients (B^{m}ₙ, O^{m}ₙ), and component operators (x, z) of the magnetic field, and after choosing the space of real numbers and carrying out the calculations with the |L, S, L_{z}, S_{z}> basis, while generating the matrix containing the products of the matrix elements of Stevens operators and defined Stevens coefficients (B^{m}ₙ, O^{m}ₙ), and component operators (x, z) of the magnetic field, at first, an empty matrix is created with rows and columns numbered with |L_{z}, S_{z}> combinations, which, as an initially prepared Hamiltonian matrix, is filled with components of Stevens operators (B^{m}ₙ, O^{m}ₙ), component operators (x, z) of the magnetic field and components of the spin-orbit coupling operator.

Alternatively, after choosing the space of real numbers and complex numbers, and carrying out the calculations in the |L,S,J,J_{z}> basis, while generating the matrix containing fillings with the products of the matrix elements of Stevens operators and defined Stevens coefficients (B^{m}ₙ, O^{m}ₙ), and component operators (x, y, z) of the magnetic field, at first, an empty matrix is created with rows and columns numbered with values of |J_{z}>, the matrix being filled with products of the matrix elements of Stevens operators and defined Stevens coefficients (B^{m}ₙ, O^{m}ₙ), total moment projection operators and component operators (x, y, z) of the magnetic field, and after choosing the space of complex numbers and carrying out the calculations with the |L, S, L_{z}, S_{z}> basis, while generating the matrix containing the products of the matrix elements of Stevens operators and defined Stevens coefficients (B^{m}ₙ, O^{m}ₙ), and component operators (x, y, z) of the magnetic field, at first, an empty matrix is created with rows and columns numbered with |L_{z}, S_{z},> combinations, which, as a Hamiltonian matrix, is filled with components of Stevens operators (B^{m}ₙ, O^{m}ₙ), projection operators of total spin and orbital magnetic moments, component operators (x, y, z) of the magnetic field and components of the spin-orbit coupling operator.

Preferably, after filling with products of the matrix elements of Stevens operators and defined Stevens coefficients (B^{m}ₙ, O^{m}ₙ), projection operators of total spin and orbital magnetic moments, component operators (x, z) or (x, y, z) of magnetic the field and optionally with components of the spin-orbit coupling operator, diagonalisation of the Hamiltonian matrix is carried out, and after the diagonalisation of the Hamiltonian matrix, n-complete sets of pairs of energy eigenvalues Eⁱ (i=1 . . . n) and eigenfunctions being linear combinations of basis vectors are calculated, and next, based on their form, the expected values of the directional components (x,z) or (x,y,z) of magnetic moments of the individual n-eigenstates of energy Eⁱ are calculated.

N-eigenstates of energy Eⁱ may be sorted with their expected values of directional components of magnetic moments <mⁱᵢ> (i=1 . . . n, j=x,z or j=x,y,z) of the individual states, and next, the sum of states Z(T) and population Nⁱ(T) of every energy state of the obtained structure are calculated in defined temperature increments according to Boltzmann statistics, based on which courses of temperature dependencies of free energy, internal energy, entropy, magnetic susceptibility, calculated for a field applied along x and z or x, y and z directions, and Schottky specific heat are calculated in order to determine the calorimetric, electron and magnetic properties of a material containing ions in the defined environment of the crystal field (CEF).

Preferably, a new complete set of result data is created, containing the calorimetric, electron and magnetic properties of a material containing ions in the defined environment of the crystal field (CEF) together with an interactive visualisation of this environment and calculation parameters, and the new complete set of result data is presented in the form of an independent complete set of data available directly and in parallel with other result data, enabling direct comparisons of the obtained results.

Various separate complete sets of the result data may be archived in a single merged numerical form together with the data pertaining to calculations, simulations and visualisations of every separate complete set of the result data, and the numerical form of the result data enables access to a chosen property or a course of the temperature dependency of the chosen property from different complete sets of the result data simultaneously.

Preferably, the form of the result data enables implementation of the saved result data and comparison with adequate current calculations.

The object of the present invention is also to provide a system for optimisation of a method for determining material properties when searching for materials having defined properties that has a computing unit with a processor and a device for presentation of data and calculation results, and with access to data on materials, and a testing unit carrying out tests on real materials and communicating with the computing unit, the processor comprises a module for finding and defining elements of the chosen material, enabling determination of their electron configuration based on values of quantum numbers of orbital magnetic moment L, spin magnetic moment S and optionally total magnetic moment J, and a module for finding a complete set of Crystal Electric Field (CEF) coefficients, defined by Stevens coefficients with the form of B^{m}ₙ, communicating with a module for construction of a model of an ideal material containing defined ions, the ions being spatially oriented identically and not interacting with each other, but interacting with external fields, with a calculated structure of energy states together with their spectral properties, and being subjected to classical Boltzmann statistics, and having directional (x, y, z) or (x, z) components of magnetic properties calculated, the module for construction of a model of the ideal material being connected with the testing unit in order to verify the model of the ideal material with a real material in a module for comparison of the ideal material with the real material, when the properties of the material obtained from calculations correspond to the properties of the material being searched for.

The module for construction of the model of the ideal material may contain a module for calculation of complete sets of pairs of the energy eigenvalues Eⁱ (i=1 . . . n) and eigenfunctions being linear combinations of basis vectors, and a module for calculation of courses of temperature dependencies of free energy, internal energy, entropy, magnetic susceptibility, calculated for a field applied along x and z or x, y and z directions, and Schottky specific heat in order to determine the calorimetric, electron and magnetic properties of a material containing ions in the defined environment of the crystal field (CEF).

### BRIEF DESCRIPTION OF THE DRAWINGS

This and other objects as well as advantageous features of the technical concept presented herein are accomplished in accordance with a principle of presented technical concept by providing a system for optimisation of a method for determining material properties at finding materials having defined properties. Further details and features of the system as well as the optimisation of a method for determining material properties at finding materials having defined properties, based particularly on the knowledge of Crystal Electric Field (CEF), their nature and various advantages will become more apparent from accompanying drawings and following detailed description of a preferred embodiment shown in a drawing, in which:

FIG. 1 shows a system for optimisation of a method for determining material properties when searching for materials having defined properties and optimisation of a method for determining material properties when searching for materials having defined properties;

FIG. 2 shows a block diagram of a computing unit;

FIG. 3 shows a block diagram of a model of an ideal material;

FIGS. 4A-4D show a block diagram of optimisation of a method for determining material properties when searching for materials having defined properties;

FIGS. 5A-5E show a block diagram of calculations of energy eigenvalues together with the wave functions corresponding to them;

FIG. 6 shows a three-dimensional visualisation of CEF for praseodymium ions in a PrCl₃ crystal;

FIG. 7 shows a matrix for praseodymium ions in a PrCl₃ crystal;

FIG. 8 shows a diagram of energy states;

FIG. 9 shows entropy vs. temperature;

FIG. 10 shows the temperature dependency of the specific heat component originating from praseodymium ions;

FIG. 11 shows a visualisation of magnetic susceptibility in an inverse form;

FIG. 12 shows a fragment of the Hamiltonian matrix, constructed in the space spanned across a body of complex numbers;

FIG. 13 shows a structure of states with the ground state and a group of states marked;

FIG. 14 shows a visualisation of the course of magnetic susceptibility vs. temperature, for all spatial components;

FIG. 15 shows a three-dimensional visualisation of CEF for nickel ions in nickel(II) oxide NiO;

FIG. 16 shows a matrix of nickel ions in nickel(II) oxide NiO;

FIG. 17 shows a diagram of energy states with the ground state and a group of next states marked;

FIG. 18 shows a diagram of magnetic susceptibility measured for a field applied in parallel to the x and z axes;

FIG. 19 shows a diagram of the splitting of a ground triplet into singlet components;

FIG. 20 shows a diagram of the specific heat c(T) course, entropy course; and

FIG. 21 shows a diagram of magnetic susceptibility for all spatial components.

### DETAILED DESCRIPTION OF EMBODIMENTS

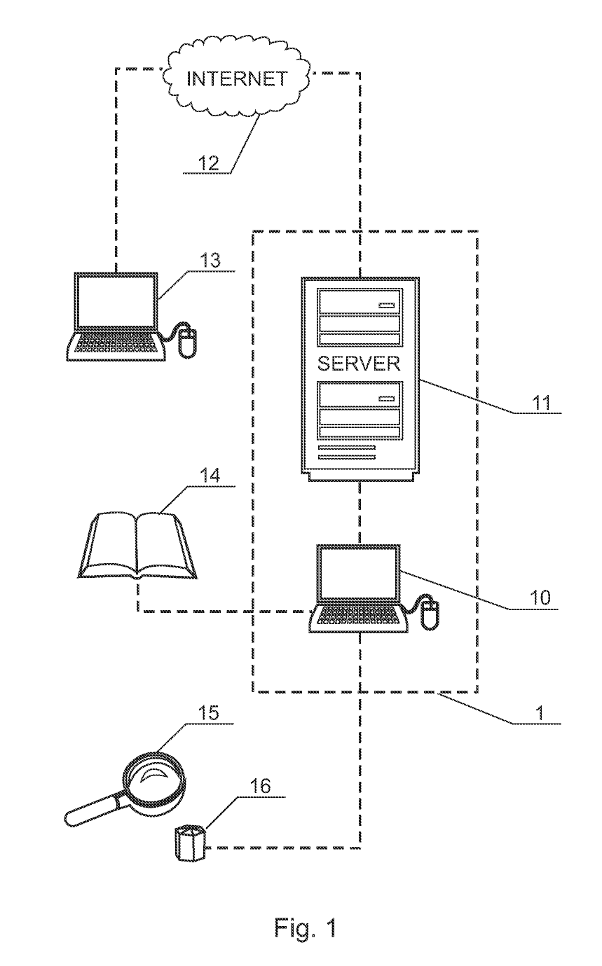

A system 1 for optimisation of a method for determining material properties when searching for materials having defined properties, particularly materials containing elements chosen from Periodic Table having at least one kind of ions with electron subshell containing a number of electrons starts from 1 to value adequate to situation called a closed electron subshell (e.g. for subshell s=2, p=6, d=10 and f=14), is shown schematically in FIG. 1. Such subshell, according to atomic physic and physical chemistry nominalism, is called an unclosed atomic subshell s,p,d or f and is the object of simulation and a starting point of physical analysis of influence of existence such ions for bulk properties of materials containing them. The system 1 contains a computing unit able to create a model of an ideal material, which has properties, if not the same, are close to those of the material being searched for. Before construction of the model of the ideal material, a material is chosen, hereinafter called the chosen material, containing atoms of elements with given properties. Most often, the properties of such chosen material are not known, but based on the state of knowledge available via a server 11 in a base 13 of the state of art, via Internet 12 or in a base 14 of the state of art in paper form, it may be expected that the chosen material will have properties at least close to the properties of the material being searched for. A computing unit 10 has a possibility to communicate with the mentioned bases 13, 14. Moreover, the computing unit has a possibility to communicate with a station 15, in which tests of a tested material 16 imitating the model of the ideal material are carried out.

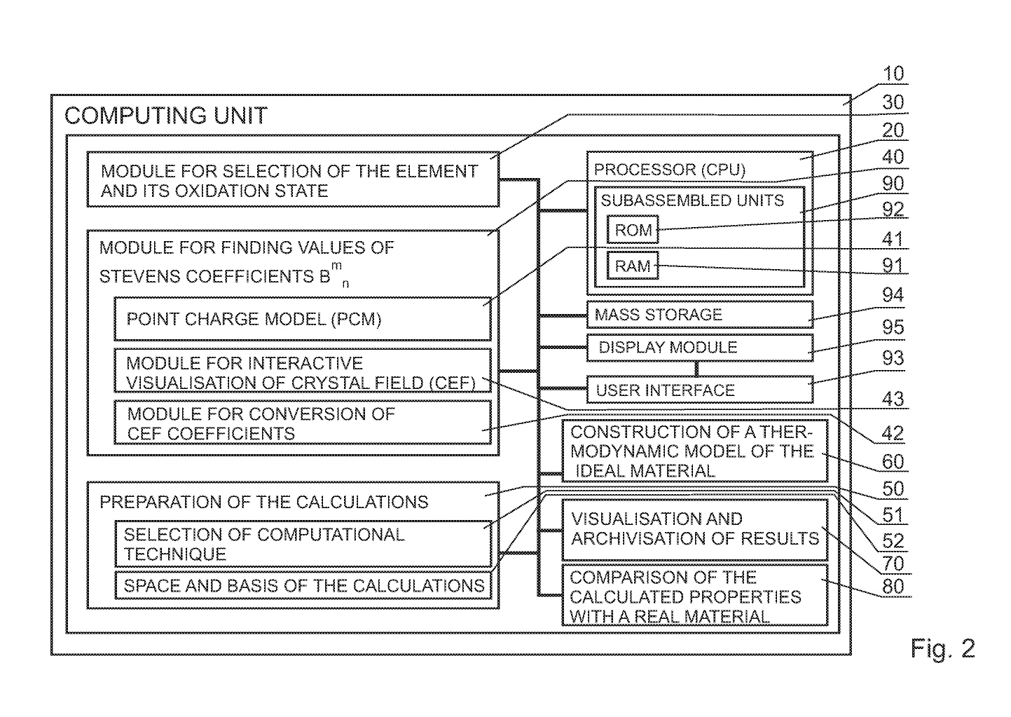

FIG. 2 schematically shows the computing unit 10, containing a processor 20 and other subassemblies 90 such as ROM 92, RAM 91, mass storage 94, a display module and a display monitor 95 and a user interface 93 enabling communication with the system. The computing unit contains a module 30 for selection of the element and its oxidation state, a module 40 for finding values of coefficients in the form B^{m}ₙ with a module 41 of the Point Charge Model (PCM), a module 43 for interactive visualisation of CEF and a module 42 for conversion of CEF coefficients. Moreover, the processor contains a module 50 for preparation of data for the calculations with a module 51 for selection of computational technique and a module 52 for determination of input data, space and basis of the calculations, as well as a module 60 for construction of a model of the ideal material, a module 70 for visualisation and archiving and a module 80 for comparison of the ideal material with a real material.

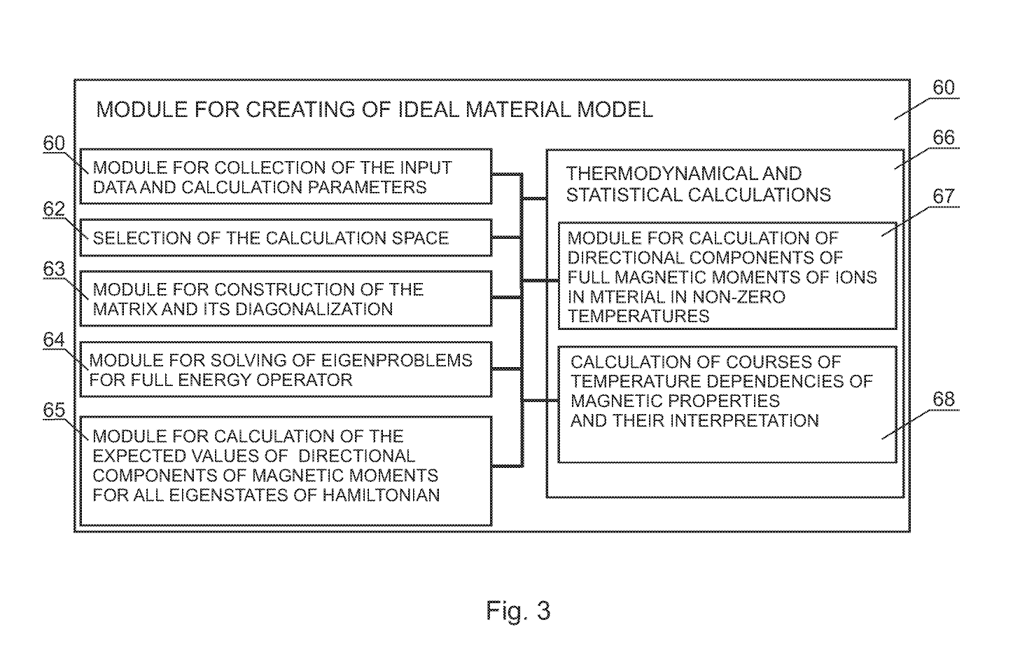

Next, FIG. 3 schematically shows the module 60 for construction of the model of the ideal material of the computing unit 10. The module 60 contains a module 61 for collection of the input data and calculation parameters, a module 62 for selection of the calculation space, a module 63 for construction of the matrix and its transformation, a module 64 for solving of eigenproblems, a module 65 for calculation of the expected values of magnetic moments and their verification, a module 66 for statistical calculations, a module 67 for calculation of directional components and a module 68 for calculation of courses of temperature dependencies and their interpretation.

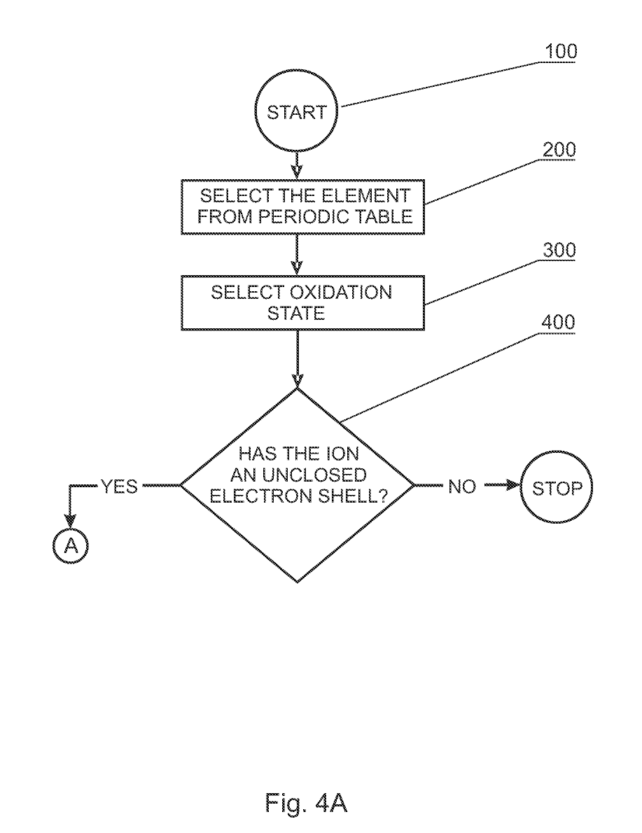

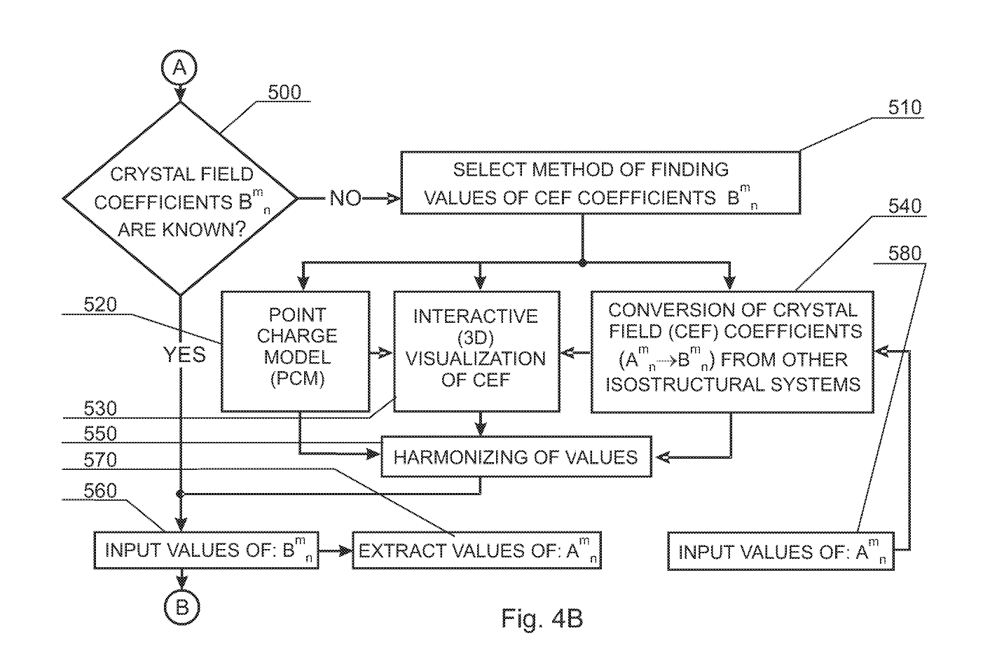

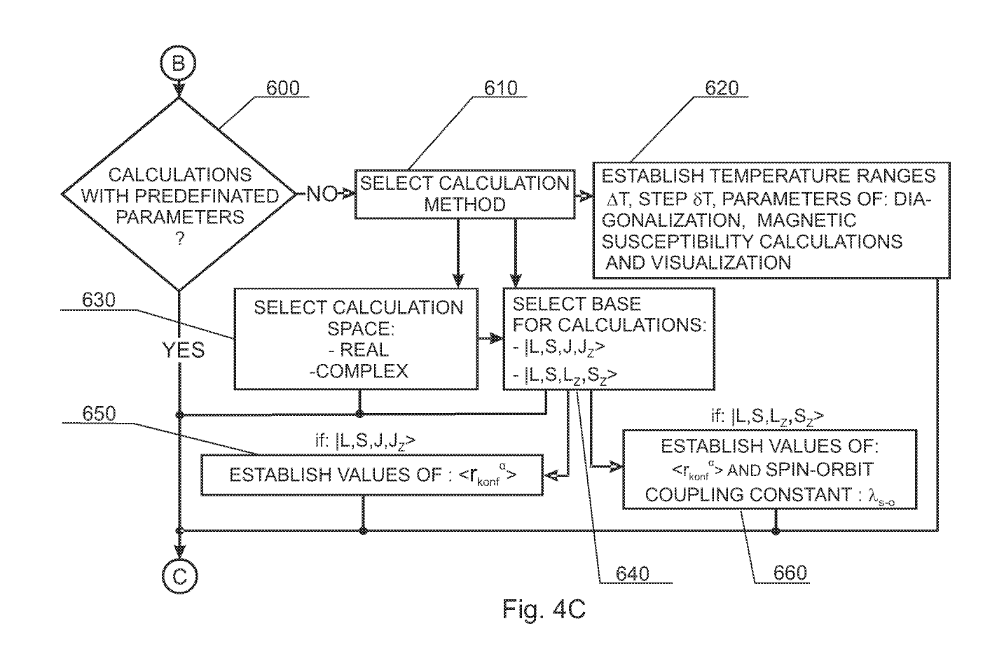

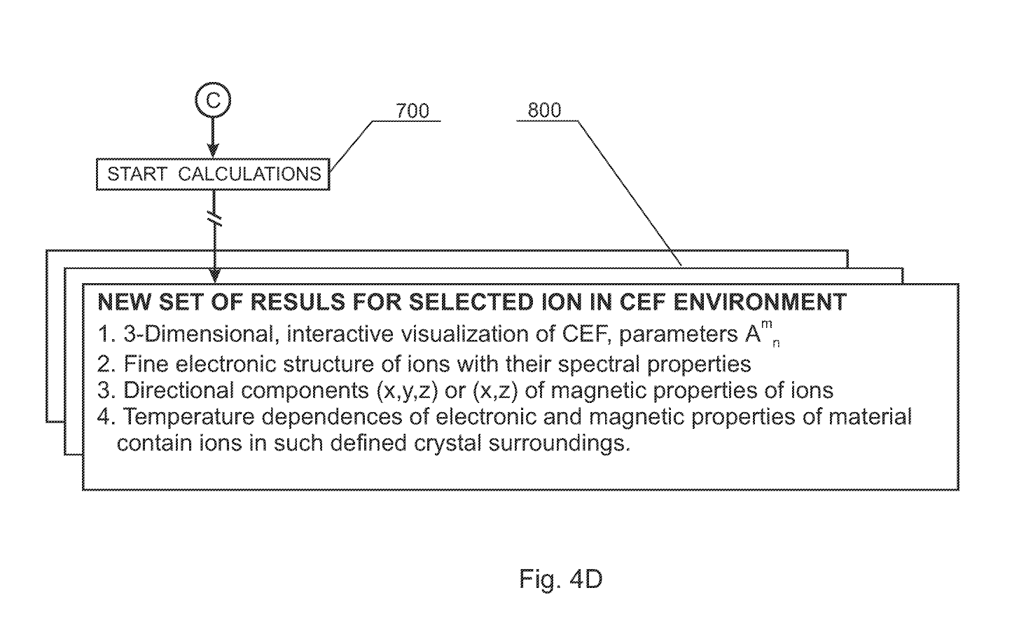

As results from a block diagram of optimisation of a method for determining material properties when searching for materials having defined properties shown in FIG. 4A-4D, after a start in step 100, an ion being the basis for calculations and material simulations is defined by choosing an element directly from the Mendeleev Table or the Periodic Table in step 200. The individual steps define the subject of optimisation so as to realise the possibilities of the given naturally occurring material by default and according to the current state of art, as well as to enable studies in areas unknown or inconsistent with the canon. The properties of the defined material, in case of ionic complexes or coordination compounds, will eventually be determined by the unclosed electron shell; thus, within the framework of the adopted technique, the oxidation state of atoms of the chosen element is determined in step 300. According to the current valid state of knowledge, it unequivocally defines the electron configuration being the basis for calculations. The determined electron configuration, defined based on rules of quantum mechanics and the chemistry of atoms, automatically determines the values of total spin quantum numbers: L, defining the orbital moment, S, defining the spin moment, and optionally J, defining the total moment, the quantum numbers corresponding to the ground state on Hund's rules, from which the first Hund's rule states that the ground state of a multiplet structure has a maximum value of S allowed by the Pauli exclusion principle, the second Hund's rule states that the ground state has a maximum allowed L value, with maximum S, and the third Hund's rule states that the primary multiplet has a corresponding J=|L−S| when the shell is less than half full, and J=L+S, where the fill is greater.

The values of quantum numbers L, S and optionally J, determined based on the above rules, construct a space for calculations constituting the essence of optimisation. In step 400, the fact whether the ion has an unclosed electron shell is checked, and the procedure is continued, depending on the fact whether the so-defined ion has an unclosed electron shell or not. After choosing the ion, its immediate charge environment in the crystal lattice is determined.

The procedure of optimisation is continued by checking in step 500 whether the crystal field coefficients B^{m}ₙ are known, and if they are known, the coefficients B^{m}ₙ are introduced in step 560. This means that knowledge of a complete set of the crystal field coefficients developed according to the adopted convention allows for them to be passed on directly to the calculations.

The charge environment is parameterised within the framework of the procedure principles by its expansion into a series of multipoles with various spatial configurations, in which a first multipole is a dipole, the next multipole is a quadrupole and so on, and in which the weight of the contribution of the determined electrical multipoles is defined by A^{m}ₙ coefficients, and the form of functions determining the spatial distribution of the potential of the individual, more significant multipoles in Cartesian coordinates is presented by the following formulas:

V₂⁰=3z²−r² V₆⁰=231z⁶−315r²z⁴+105r⁴z²+5r⁶

V₂²=x²−y² V₆²=[16z⁶−16(x²+y²)z²+(x²+y²)²](x²−y²)

V₄⁰=35z⁴+30r²z²+3r V₆³=(11z²−3zr²)(x³−3xy²)

V₄²=(7z²−r²)(x²−y²) V₆⁴=(11z³−r²)(x⁴−6x²y²+y⁴)

V₄³=z(x³−3x y²) V₆⁶=x⁶−15x⁴y²+15x²y⁴−y⁶

V₄⁴=(x⁴−6x²y²+y⁴)

where: r²=x²+y²+z²

According to the current state of knowledge, there are operators operating in quantum spaces with symmetry properties identical to the potentials defined above in the real space. These operators are Stevens operators Oⁿₘ operating in spaces defined by spin quantum numbers. Thus, a classical Hamiltonian of the crystal field for the potential of the series of multipoles may be defined:

$${H}_{CEF} = {\sum }_{m , n} {A}_{n}^{m} {V}_{n}^{m} ( x , y , z )$$

Based on the current state of knowledge, an analogous CEF Hamiltonian is defined in the space of spin quantum numbers, with the form:

$${H}_{CEF} = {\sum }_{n} {\sum }_{m} {B}_{n}^{m} {\hat{O}}_{n}^{m} ( L , {L}_{z} )$$

In the above analogous CEF Hamiltonian, the contribution of multipoles is defined by CEF coefficients, called Stevens coefficients with the form B^{m}ₙ. The method for conversion of coefficients A^{m}ₙ→B^{m}ₙ between the classical and quantum spaces, based on the rules of quantum mechanics, by dynamically calculated Clebsch and Gordon coefficients based on defining expressions, constitutes the foundation of visualisation possibilities of CEFs within the framework of the optimisation being carried out and conversion of values of the coefficients between isostructural compounds with various ionic ligands after transition from step 580 to step 540.

In case the crystal field coefficients B^{m}ₙ are not known, selection of the method for finding the values of crystal field coefficients B^{m}ₙ is carried out in step 510. It should be noted that in the majority of cases, determination of Stevens coefficients together with their all related parameters is the biggest difficulty when using methods originating from atomic physics. Depending on the selection of the method in step 520, the calculations of Stevens coefficients with the form B^{m}ₙ are carried out using the Point Charge Model (PCM); in step 530, the calculations are carried out using an interactive three-dimensional (3D) visualisation of the crystal field (CEF) components; and in step 540, the calculations are carried out by a conversion of crystal field (CEF) coefficients A^{m}ₙ→B^{m}ₙ from known results of other calculations for systems isostructural with the one being calculated, but containing other ions. After completion of the calculations, in step 550, the values of Stevens coefficients are harmonised. The process is based on an analysis of the spread of the coefficient values obtained by various methods, then, on a verification of the result values in comparison with the known experimental data or theoretical relations connecting the values of parameters in case of specific symmetries of the crystal lattice by proportions. While determining the complete set of the crystal field coefficients corresponding to the defined spatial distribution of the electrical charge, it may be additionally interactively visualised and compared with the point charge model PCM in step 530. Also, in step 570, the values of coefficients may be compared and converted by extraction of values of universal parameters characterising the crystal lattice A^{m}ₙ from the form B^{m}ₙ of Stevens coefficients useful for the calculations, after transition to step 540.

Ultimately, input of the start data occurs in steps 600, while in steps 610, 620, 630, 640, 650, and 660, selection of the method is carried out. These steps allows for collecting of all the necessary data in order to correctly define the input data for the calculations. In a case where calculations with predefined calculations are chosen, the calculations will be carried out in a full |L,S,L_{z},S_{z}> basis, with the value of the spin-orbit coupling constant λₛ₋ₒ assumed as a free ion, in the space of complex numbers which allows for obtaining of results with all three directional components in space. In a case where a vector space spanned across a body of real numbers and the |L,S,J,J_{z}> basis are chosen, complete results are not obtained in step 640; however, considering the significantly faster calculations, they are useful in cyclic calculations, for instance in order to search for a proper complete set of CEF parameters in connection with the result properties.

After carrying out the calculations in step 700, a complete set of the result data is presented in step 800.

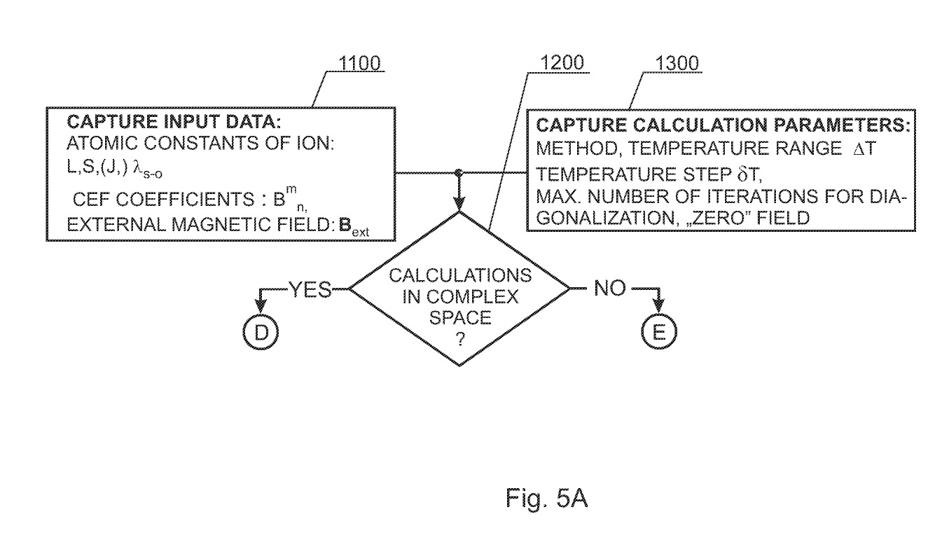

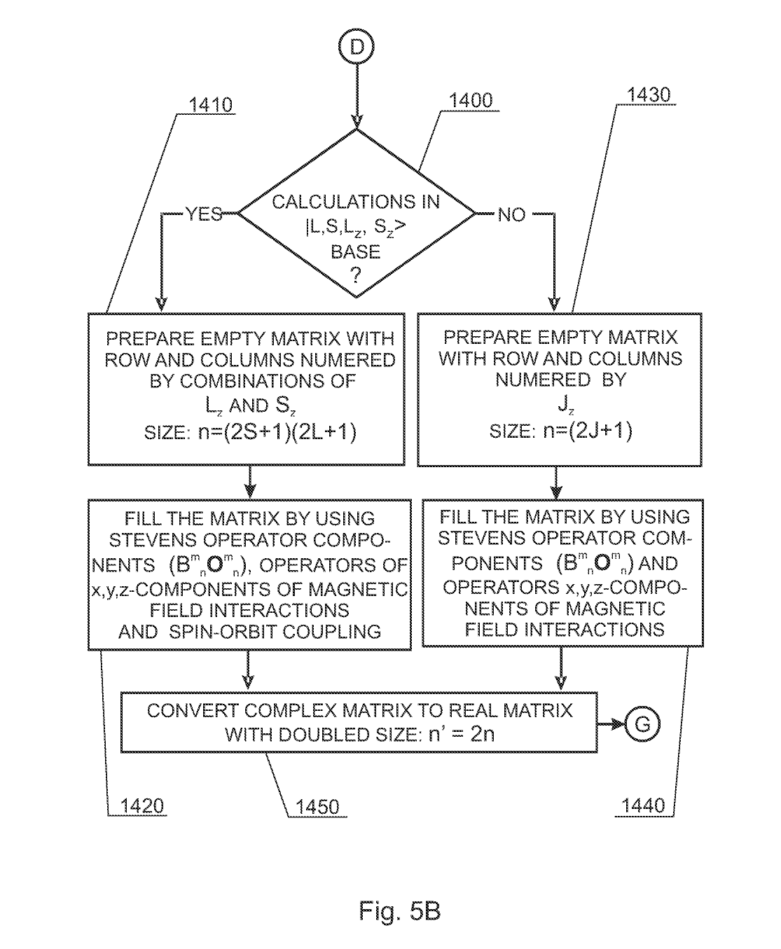

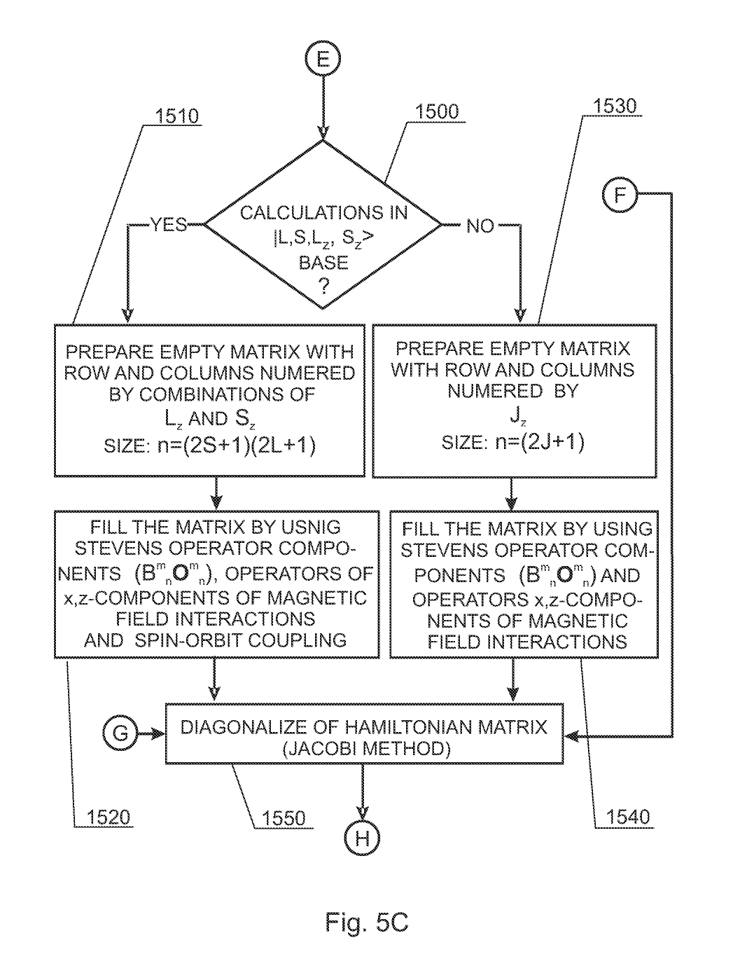

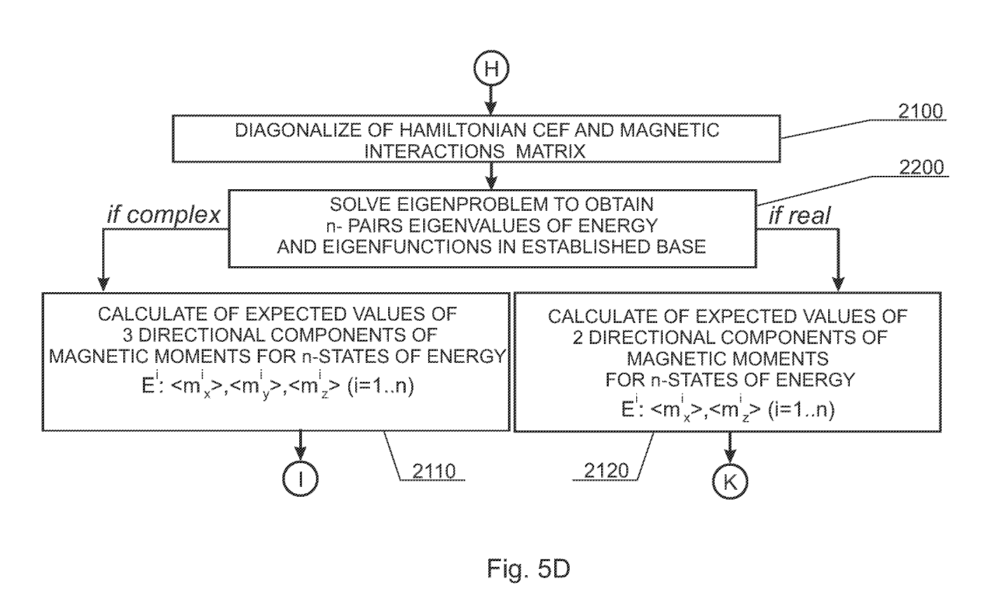

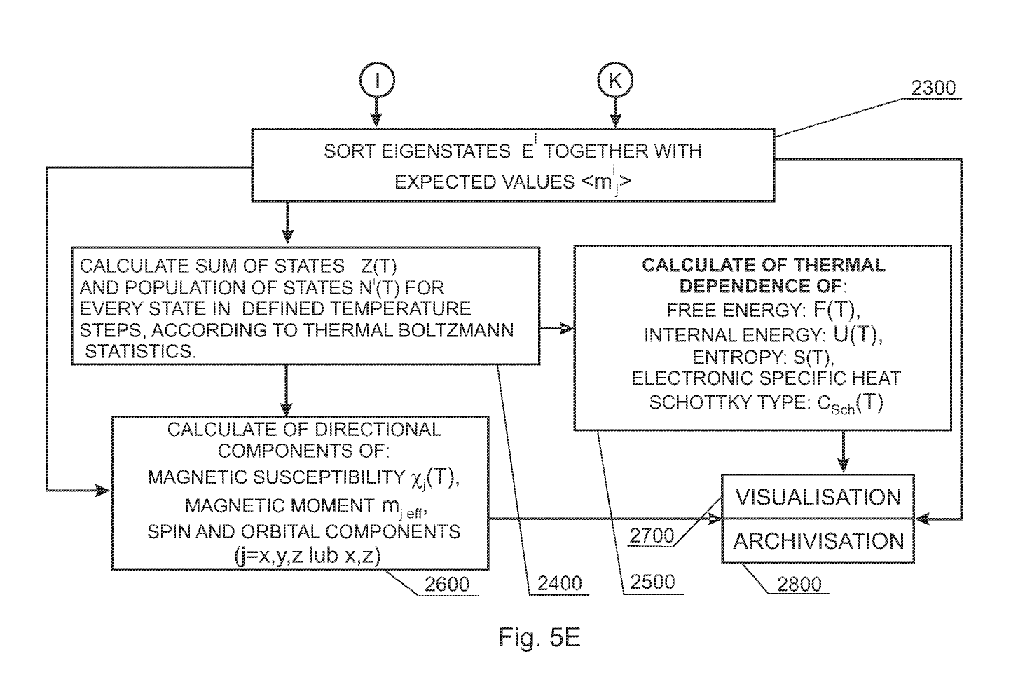

FIGS. 5A-5E show a block diagram of calculations of energy eigenvalues together with the wave functions corresponding to them. The first five steps 1100, 1200, 1300, 1400, 1500 illustrate the method for setting up the calculation procedure in response to the entered parameters concerning the technique of calculations. In this moment, the ion is already determined, and the values of magnetic quantum numbers L and S corresponding to the ground state according to the fundamentals of the atom physics are known, e.g. in case of Cr³⁺→ion L=3, S=3/2. Depending on the adopted input setting, step 1410 or 1430 or 1510 or 1530 is carried out by generating an empty matrix with a dimension dependent on quantum number L of the total orbital magnetic moment of the whole unclosed shell, and quantum number S of the total spin moment of the whole unclosed shell, or on quantum number J of the total moment of the whole unclosed shell corresponding to a combination of basic values of L and S, if J is a good quantum number in the specific case. This name has no precise definition—it results from the practice of theoretical calculations, when it is sometimes possible to use it in a theoretical description (4f, 5f configurations), when the assumption that the states of the ground multiplet are so distant from the states of the first excited multiplet that their influence may be omitted, is correct. Sometimes, unfortunately, it is impossible (3d, 4d configuration), when the states interpenetrate, and number J is unjustified—and the spin-orbital coupling should be included into the calculations with a finite value of the coupling constant, obtaining a structure of states of the whole term. The created matrix has rows and columns numbered with the available values of a combination of quantum numbers of z^{th} component of the total orbital magnetic moment, spin magnetic moment L_{z}, S_{z} or optionally with values of z^{th} component or element of total moment J_{z} with z indices, because z coordinate axis is the main axis of the Hamiltonian's quantisation. According to the fundamental rules of quantum mechanics, L_{z} assumes values of the range from −L to L, with the increment equal to 1, S_{z} analogically assumes values of the range from −S to S, and similarly, J_{z} assumes values of the range from −J to J. In the case of the Cr³⁺ example, it means that L_{z} will assume values L_{z}=−3,−2,−1,0,1,2,3, and S_{z}=3/2,−1/2,1/2,3/2; therefore, n=(2S+1)(2L+1) possible various combinations, for instance in case of Cr³⁺ n=28. Unique L_{z}, S_{z} pairs are the discriminant of a row or column in the so-created matrix. The above assumption of values pertains to the |L,S,L_{z},S_{z}> basis in steps 1410 and 1430.

In case of calculations in a constrained basis |L,S,J,J_{z}>, the calculations are carried out only for the ground multiplet, or degenerated state of the electron structure of a free ion, for which L, S and J numbers are determined, where CEF and magnetic interactions lift the multiplet degeneration, leading to formation of a structure of separated energy states, and not—as in the above case—for the whole structure of the ground term, or degenerated state of the electron structure of a free ion, for which L, S numbers are determined, where CEF and magnetic interactions lift the degeneration of the whole term, together with possible multiplets, leading to formation of a structure of separated energy states. Therefore, in this case (|L,S,J,J_{z}>), no constant of spin-orbital coupling λₛ₋ₒ is defined, and its value is assumed conceptionally as infinite. In spite of the clearly simplified character of such calculations, they are considered correct, e.g. for rare earth metal ions Nd³⁺→L=6, S=3/2, J=9/2, the size of the created matrix is n=(2J+1)=10; thus columns and rows of the matrix will by numbered with values of J_{z}=−9/2,−7/2,−5/2,−3/2,−1/2,1/2,3/2,5/2,7/2,9/2.

The method of filling of the created matrices, carried out in steps 1420, 1440, 1520, 1540, is based on the applied total energy operator, the so-called Hamiltonian, of the crystal field (CEF), and magnetic interactions in the form of internal spin-orbital coupling, and interaction with external magnetic field Bext defined by the user. Depending on the selected basis, i.e. |L,S,L_{z},S_{z}>, the Hamiltonian has the following form:

$${H}_{LS} = {\sum }_{n} {\sum }_{m} {B}_{n}^{m} {\hat{O}}_{n}^{m} ( L , {L}_{z} ) + λ L \cdot S + {μ}_{B} ( L + {g}_{e} S ) \cdot {B}_{ext}$$

It should be noted that in the |L,S,J,J_{z}> basis, the form of the Hamiltonian does not contain the spin-orbit interaction, because in this model, an infinitely strong L and S coupling is assumed, resulting in a so-called good quantum number J, with values running through the J=L+S . . . |L−S| range, and the third Hund's rule determines its value for the ground multiplet. In such a case, the Hamiltonian assumes the following form:

$${H}_{J} = {\sum }_{n} {\sum }_{m} {B}_{n}^{m} {\hat{O}}_{n}^{m} ( J , {J}_{z} ) + {g}_{L} {μ}_{B} J \cdot {B}_{ext}$$

Filling of the Hamiltonian matrix with elements or components in the |L,S,L_{z},S_{z}> basis is defined by the rules of construction of a matrix of angular momentum operators, and the construction itself is explained below. All Stevens operators O^{m}ₙ and operators of interaction with an external field are generated from fundamental components or elements in the following way:

<L,L_{z}|L_{z}|L,L_{z}>=L_{z}

<S,S_{z}|S_{z}|S,S_{z}>=S_{z}

<L,L_{z}±1|Lₓ|L,L_{z}>=½\sqrt{(L∓L_{z})(L±L_{z}+1)}

<S,S_{z}±1|Sₓ|S,S_{z}>=½\sqrt{(S∓S_{z})(S±S_{z}+1)}

Vertical dashes | separate the individual row elements, and a given row should be read as follows: <row|matrix element of the operator|column>=value of this element.

Therefore, the elements of the component spin-orbital matrix should be inserted into positions of the matrix according to the following recipe:

$$〈 L , S , {L}_{z} , {S}_{z} \vert λ L \cdot S \vert L , S , {L}_{z} , {S}_{z} 〉 = λ {L}_{z} {S}_{z}$$

$$〈 L , S , {L}_{z} , {S}_{z} \vert λ L \cdot S \vert L , S , {L}_{z} \pm 1 , {S}_{z} ∓ 1 〉 == \frac{1}{2} λ ( \sqrt{L ( L + 1 ) - {L}_{z} ( {L}_{z} \pm 1 )} \sqrt{S ( S + 1 ) - {S}_{z} ( {S}_{z} ∓ 1 )} )$$

Now, it is noteworthy that important commutation relations between the spin operators exist, allowing for constructing operators of directional components of L₊=Lₓ+i L_{y} and L_=Lₓ−i L_{y} moments. This concerns any spin operators of one kind, thus:

J₊=Jₓ+i J_{y} and J_=Jₓ−i J_{y}

where “i” is an imaginary number i=(−1)^{1/2}, and the notation of numbers of such a type requires using special, double matrices, which is carried out in steps 1410 and 1430.

Analogically, in the case of the |L,S,J,J_{z}> basis, the elementary operators are generated as follows:

$$< J , {J}_{z} \vert {J}_{z} \vert J , {J}_{z} >= {J}_{z} \\ < J , {J}_{z} + 1 \vert {J}_{+} \vert J , {J}_{z} >= < J , {J}_{z} \vert {J}_{-} \vert J , \\ {J}_{z} + 1 >= \frac{1}{\sqrt{2}} \sqrt{( J - {J}_{z} ) ( J + {J}_{z} + 1 )}$$

Ô₀⁰=1 Ô₁⁰=J_{z} Ô₁¹=½(J₊+J₋)

Ô₂⁰=3J_{z}²−J(J+1)

Ô₂¹=¼[(J_{z}J₊+J₋J_{z})+(J_{z}J₋+J₋J_{z})]

Ô₂²=½(J₊²−J₋²)

Ô₄⁰=35J_{z}⁴−[30J(J+1)−25]J_{z}²+3J²(J+1)²−6J(J+1)

Ô₄²=[7J_{z}⁴−J(J+1)−5](J₊²+J₋²)+(J₊²+J₋²)[7J_{z}⁴−J(J+1)−5]

Ô₄³=¼[J_{z}(J₊³+J₋³)+(J₊³+J₋³)J_{z}]

Ô₄⁴=½(J₊⁴+J₋⁴)

Ô₆⁰=231J_{z}⁶−[315J(J+1)−736]J_{z}⁴+[105J²(J+1)²−525J(J+1)+294]J_{z}²+−5J³(J+1)³+40J²(J+1)²−60J(J−1)

Ô₆²=¼{{337J_{z}⁴−[18J(J−1)+123]J_{z}²+J²(J+1)²+10J(J+1)+102}(J₊²+J²)++(J₊²+J₋²){337J_{z}⁴−[18J(J+1)+123]J_{z}²+J²(J+1)²+10J(J+1)+102}

Ô₆³=¼{[11J_{z}³−3J({i J+1)J_{z}−59J_{z}](J₊³+J₋³)−(J₊³+J₋³)[11J_{z}³−3J(J+1)J_{z}−59J_{z}]}

Ô₆⁴=¼{[11J_{z}²−J(J+1)−38J_{z}](J₊⁴+J₋⁴)+(J₋⁴+J₋⁴)[11J_{z}²−J(J+1)−38J_{z}]}

Ô₆⁶=½(J₊⁵+J₋⁶)

Thus, generation of the CEF Hamiltonian matrix in the |L,S,J,J_{z}> basis, carried out in steps 1440 and 1540, resolves itself into insertion of the determined values of products of the B^{m}ₙ coefficients with definition constants into the coordinates defining the row <J_{z}| and the column |J′_{z}> of operators obtained in the result of substitution of relations for J₊, J₋ and J_{z} into the above definitions, into the created matrix.

In the case of generation of the Hamiltonian CEF matrix in the |L,S,L_{z},S_{z}> basis, the component relations of Stevens operators O^{m}ₙ are identical as above, but they describe the operators of the orbital magnetic moment, because CEF does not interact directly onto spin S, or:

Ô₀⁰=1 Ô₁⁰=L_{z} Ô₁¹=½(L₊+L₋)

Ô₂⁰=3L_{z}²−L(L+1)

Ô₁¹=¼[(L_{z}L_{|}+L_{|}L_{z})+(L_{z}L+LL_{z})]

Ô₂²=½(L₊²+L₋²)

Ô₄⁰=35L_{z}⁴−[30L(L+1)−25]L_{z}²+ . . .

However, generation of the Hamiltonian CEF matrix in the |L,S,L_{z},L,> basis, carried out in steps 1420 and 1520, resolves itself into insertion of the determined values of products of the B^{m}ₙ coefficients with definition constants into the coordinates defining the row <L_{z}| and column |L'_{z}> of operators obtained in the result of substitution of relations for L₊, L₋ and L_{z} into the above definitions, into the created matrix.

According to the presented relations, Hamiltonian matrices are created automatically in order to bring them, in the next step 1550, to a diagonal form in step 1200, in order to solve the so-called eigenequation of the operator or to obtain pairs of vectors and eigenvalues of the operator, in this case total energy operator, the so-called Hamiltonian.

In case of a matrix with complex elements, the created complex matrix is distributed in step 2210 into a system of real matrices with terms containing only real components and only imaginary component values, and then, according to the rules of matrix analysis, they are concatenated into a matrix with a doubled dimension n′=2n. Such an operation, based on the theorems on complex matrices, allows for carrying out of further calculations of complex matrices analogously as for real matrices. In particular, the diagonalisation procedure carried out in step 2100, or numerical bringing the matrix by arbitrary addition, subtraction and multiplication by the numbers of rows and columns in order to obtain the state in which non-zero elements are located only in the cells of the matrix having the same row number and column number, is universal for all situations. Diagonalisation of the matrix is carried out according to the Jacobi method, based on numerical recurrent techniques. The diagonalisation procedure of the created matrices requires an assumption of a proper diagonalisation precision parameter, influencing the duration of calculations to a very high extent. Considering the recurrent character of the diagonalisation process, an ideal diagonalisation never ends; therefore, the moment of stopping the calculations depends on the accuracy parameter—its value is configurable, but low enough (of the order of 10⁻¹²-10⁻¹⁴) to be numerically treated as zero. The constants numerically defining the moment of stopping the diagonalisation procedure, by determination of the maximum number of iteration and minimum inaccuracy value, are defined in step 1200 each time the calculations start during the diagonalisation procedure.

The obtained matrix in the diagonal form constitutes a base for obtaining a solution, the so-called Hamiltonian eigenproblem, in step 2200—or obtaining the energy eigenvalues, the so-called permissible energy levels together with wave functions corresponding to them and being linear combinations of basis vectors, resulting from the adopted basis and method. According to the foundations of quantum mechanics, normalised wave functions allow for calculating the expected values of observables, the so-called physical quantities connected with an operator creating them, in individual states. Considering the fact that the basis for calculations is in every case based on the so-called magnetic quantum numbers L, S or J, the expected values of states calculated in steps 2210 and 2220 directly from their wave functions are directional components of the total magnetic moments of these states.

In other words, as results from the Hamiltonian defined in the |L,S,J,J_{z}> basis, with every i^{th} state of the fine structure, its magnetic moment may be related:

<mᵢ^{x}>=<Γᵢ|g_{L}μ_{B}Jₓ|Γᵢ>,<mᵢ^{y}>=<Γᵢ|g_{L}μ_{B}J_{y}|Γᵢ> or <mᵢ^{z}>=<Γᵢ|g_{L}μ_{B}J_{z}|Γᵢ>

Analogically, in the case of the |L,S,L_{z},L,> basis:

<mᵢ^{x}>=<Γᵢ|μ_{B}(Lₓ+gₑSₓ)|Γᵢ>, <mᵢ^{y}>=<Γᵢ|μ_{B}(L_{y}+gₑS_{y})|Γᵢ> or <mᵢ^{z}>=<Γᵢ|μ_{B}(L_{z}+gₑS_{z})|Γᵢ>

where: g_{L}−constant called Landé g factor, defined with the following expression:

$${g}_{L} = 1 + ( 1.002324 ) \frac{J ( J + 1 ) + S ( S + 1 ) - L ( L + 1 )}{2 J ( J + 1 )}$$

where: gₑ=2.002324

μ_{B}−Bohr magneton, equal μ_{B}=9.27·10⁻²⁴ J/T, J/T≡A·m²

Considering the fact that the matrix elements or components of operators of the y component of the magnetic moment L_{y}, S_{y} and J_{y} have imaginary components and generate complex matrix elements, in the case when the calculations are limited to real matrices, this component of the individual states will not be possible to obtain in step 2220. Only z and x components of the magnetic moment of the individual states will be obtained then. In case of calculations in complex matrices, full information on the expected values of all Cartesian directional components x, y, z of the magnetic moment of the individual states, corresponding to specific energy levels calculated in step 2210, are obtained.

In step 2300, sorting and normalisation of energy eigenvalues with wave functions is carried out, being a universal procedure providing the first data for result visualisation and archiving. The energy eigenstates sorted ascending show in steps 2700 and 2800 the energy structure obtained as a result of an interaction of the defined ion with the defined charge environment of the crystal lattice. The structure of the eigenstates, together with wave functions corresponding to them and the expected values of directional components of the total magnetic moment in the individual states obtained in step 2300, calculated based on them, constitutes the basis for further calculations of material properties. Till now, precise quantum mechanic calculations of the energy structure of a single ion have been carried out. Passing to step 2400, it is assumed that a material containing the so-defined ions in its crystal structure is modelled. Thus, a model of an ideal material containing the defined ions with a calculated structure of energy states is created, the ions being spatially oriented identically, forming a perfect crystal, and not interacting with each other, but interacting with external fields, being subject to classical Boltzmann statistics. According to this statistics, at T=0 K, only the ground state is occupied. In such a case, the magnetic moment of the ion is exactly equal to the ground state moment, or its calculated expected value. While simulating an increase in temperature, the probability of occupation of higher states increases according to Boltzmann statistics. According to these statistics, the number of ions in the state with energy of Ei (population of the i^{th} state) Nᵢ(T) at a non-zero temperature T is equal to:

$${N}_{i} ( T ) = {N}_{0} \frac{exp ( - \frac{{E}_{i}}{{k}_{B} T} )}{Z ( T )}$$

where Z(T) is the sum of states calculated using the universal relation:

$$Z ( T ) = Tr ( exp ( - \frac{{\hat{H}}_{CEF}}{{k}_{B} T} ) ) = {\sum }_{i} exp ( - \frac{{E}_{i}}{{k}_{B} T} )$$

k_{B} is Boltzmann constant k_{B}=1.380488 10⁻²³ J/K, while N₀ is the initial number of ions, replaced in the case of the presented calculations with Avogadro's number N_{A}=6.02214129×10²³ mole⁻¹, yielding results converted per one mole of the defined ions of a material. While numerically calculating the sums of states of the group of defined ions in step 2400, computation parameters in the form of the temperature range ΔT and computation step σT loaded in step 1200 are adopted. Thus, the set of population values for the individual states at specific non-zero temperatures Nᵢ(T) is calculated cyclically based on Z(T) for every k^{th} temperature step Tₖ=T_{k 1}+σT.

Knowing the sum of states, free energy F(T) is calculated in step 2500, using the universal relation;

F(T)=−k_{B}T In Z(T)

which further allows for calculating the internal energy of the system of ions U(T):

$$U ( T ) = - {k}_{B} T \frac{\partial }{\partial T} ( \frac{F ( T )}{{k}_{B} T} ) = F ( T ) - T ( \frac{\partial F ( T )}{\partial T} )$$

Based on the knowledge of thermodynamic functions of state, the number of system properties based on them may be determined. The internal energy of a system of discrete states at T≠0, occupied according to classical Boltzmann statistics, converted per one mole of non-interacting paramagnetic ions, is a sum of the total energies of the individual ions.

$$U ( T ) = {N}_{A} {\sum }_{i = 1}^{ } {E}_{i} {p}_{i} = {N}_{A} {\sum }_{i = 1}^{ } \frac{{E}_{i} {n}_{i}}{Z} = {N}_{A} {\sum }_{i = 1}^{ } \frac{{E}_{i} exp ( - \frac{{E}_{i}}{{k}_{B} T} )}{( 1 + {\sum }_{j = 1}^{N} exp ( - \frac{{E}_{i}}{{k}_{B} T} ) )}$$

where N_{A} is Avogadro's number.

Specific heat, converted per one mole of ions, is defined as a temperature derivative of internal energy:

$${c}_{mol} = {( \frac{\partial U ( T )}{\partial T} )}_{{E}_{i}} = {N}_{A} \cdot {k}_{B} {\sum }_{i = 1}^{ } ( \frac{{E}_{i} exp ( - \frac{{E}_{i}}{{k}_{B} T} ) [ \begin{matrix}{E}_{i} + {E}_{i} ( {\sum }_{j = 1}^{ } exp ( - \frac{{E}_{j}}{{k}_{B} T} ) ) - \\ ( {\sum }_{j = 1}^{ } {E}_{j} exp ( - \frac{{E}_{j}}{{k}_{B} T} ) )\end{matrix} ]}{{{T}^{2} ( 1 + {\sum }_{j = 1}^{ } exp ( - \frac{{E}_{j}}{{k}_{B} T} ) )}^{2}} )$$

where the product of the Avogadro constant and Boltzmann constant is the universal gas constant N_{A}·k_{B}=R=8.31 J/K·mole.

The so-calculated electron heat is called Schottky heat or Schottky anomaly, and it constitutes a canon of thermodynamic calculations of localised electron systems.

The cₘₒₗ(T) curve has such a property that the temperature entropy change ΔS(T), calculated based on it, determines the number of unoccupied states at a temperature of T. Within the framework of the method, thermodynamic entropy is calculated by numerical integration of the obtained cₘₒₗ(T) curve in the temperature range defined in step 2500 as:

$$S ( T ) = S ( 0 ) + {\int }_{0}^{T} \frac{{c}_{mol} ( T )}{T} d T$$

The last step 2600 allows for obtaining information on the course of magnetic susceptibility of a material, based on the obtained electron structure of the defined ions with the expected values of directional components of the moments in step 2300 in the defined environment and thermodynamics of a statistical system of the above ions, calculated in the given temperature steps defined in step 2400.

Magnetic susceptibility for a paramagnetic state is calculated according to its definition as a ratio of the induced magnetisation, understood as a sum of the magnetic moments at a given temperature to the magnetic field applied. Investing the relations between the thermodynamic functions presented in the beginning of the section, one may relatively simply calculate the directional components of temperature dependency of the magnetic susceptibility of the 4fⁿ system in the crystal structure. In the limit of low external fields, the susceptibility is defined as a derivative:

$${χ}_{f}^{j} = \frac{\partial {M}_{j} ( T )}{\partial {B}_{j}} = \frac{{k}_{B} T}{{B}_{j}} ( \frac{\partial ln Z ( T )}{\partial {B}_{j}} )$$

where j (j=x, y, z) is a direction in a local coordination system connected with the axes of quantisation of an unclosed shell in CEF with a defined symmetry.

Considering the relations between the thermodynamic functions calculated in step 2500, the following expression is obtained:

$${χ}_{j} = \frac{{N}_{A} {g}_{L}^{2} {μ}_{B}^{2}}{Z} [ \frac{{\sum }_{l = k}^{ } {\vert 〈 {Γ}_{k} \vert {J}_{j} \vert {Γ}_{l} 〉 \vert}^{2}}{{k}_{B} T} exp ( - \frac{{E}_{l}}{{k}_{B} T} ) + 2 {\sum }_{l \neq k} \frac{{\vert 〈 {Γ}_{k} \vert {J}_{j} \vert {Γ}_{l} 〉 \vert}^{2}}{( {E}_{k} - {E}_{l} )} exp ( \frac{- {E}_{l}}{{k}_{B} T} ) -- \frac{1}{{k}_{B} T} {( {\sum }_{l} {\vert 〈 Γ l \vert {J}_{j} \vert {Γ}_{l} 〉 \vert}^{2} exp ( - \frac{{E}_{j}}{{k}_{l} T} ) )}^{2} ]$$

where l, k number the eigenstates of the Hamiltonian used.

For high temperatures and for very weak crystal fields, the above expression reduces itself to Curie-type susceptibility, and thus, among others, a tool in the form of processor-assigned software allows for comparing the results with a curve representing this law for a defined m_{eff} parameter.

The presented method allows for clear determining of components of the total magnetic moments of ions with an unclosed shell forming a statistical system, simulating in this way the properties of a material with a crystal structure. Knowing that the total magnetic moment of an ion consists of an orbital part and a spin part, the moment is defined by the following equality m_{c}=m_{L}+mₛ. Knowledge of the expected values of components of the angular momentum vector of the individual states allows for determining the contributions of the spin and orbital parts of the magnetic moment.

Remembering that:

J_{z}=L_{z}+S_{z}

and taking into account that gᵢ=1 and gₛ=2.002324:

m_{c}^{z}=m_{L}^{z}+m_{S}^{g} [symbol] g_{L}μ_{B}J_{z}≅1μ_{B}L_{z}+2μ_{B}S_{z}

useful dependencies are obtained:

L_{Z}=(2−g_{L})J_{Z}, S_{Z}=(g_{L}−1)J_{Z} or m_{S}≅2μ_{B}(g_{L}−1)J_{Z}, m_{L}=μ_{B}(2−g_{L})J_{Z}

From the above relations, it results that ratios of the individual components of the magnetic moment to the total moment for calculations carried out in the |L,S,J,J_{z}> basis are constant for a given ion and temperature invariant. Thus:

$$\frac{{m}_{s}}{{m}_{c}} = \frac{2 ( 2 - {g}_{L} )}{( {g}_{L} - 1 )} , \frac{{m}_{s}}{{m}_{c}} = \frac{2 ( {g}_{L} - 1 )}{{g}_{L}}$$

In case of calculations carried out in the full |L,S,L_{z},S_{z}> basis, taking the coupling between states of various multiplets into account, the values of orbital and spin components are obtained directly, because of the specifics of precise calculations.

The presented optimisation enables determination of a full three- or two-dimensional distribution of magnetic properties, namely magnetic susceptibility, effective moment, spin and orbital components, expected values of magnetic moments in states and their components, spectral properties, namely the system of states, eigenfunctions, transfer matrix of transition probability and so on, and calorimetric properties, particularly Schottky specific heat and entropy. All the above properties are simulated in the form of temperature dependencies in the range defined by the user. Information on properties at a temperature of T=0 K, where only the lowest level of the structure of states is occupied, is also available. The total magnetic moment of the system at T=0 K is equal to the moment for the ground state. Population of states in non-zero temperatures determines the atomic magnetic properties of ions, directly affecting the simulated macroscopic magnetic properties of the compound.

On the basis of the structure of multi-electron states obtained as a consequence of the above calculations in the adopted basis |L,S,J,J_{z}> or |L,S,L_{z},S_{z}> with the selection suggested for the type of ion, the following properties are predictable - as temperature dependencies obtained at a temperature range defined by the user, such as:
electron entropy Sₑ(T) connected with temperature filling of multi-electron states of the calculated electron structure of an ion or atom;
electron component of specific heat cₘₒₗ(T) connected with temperature filling of multi-electron states of the calculated electron structure of the ion or atom;
effective magnetic moment and its directional components mᵢ(B, T) in a defined coordination system;
magnetic susceptibility and its directional components xᵢ(T);
spectroscopic observability of inter-state transitions <Γᵢ|J₋|Γⱼ>, <Γᵢ|J₊|Γⱼ>, <Γᵢ|J_{Z}|Γⱼ>;
spin and orbital component of the total magnetic moment <Γᵢ|L|Γᵢ>, <Γᵢ|S|Γᵢ>.

The optimisation presented above, in a theoretical way, will now be depicted in connection with exemplary elements.

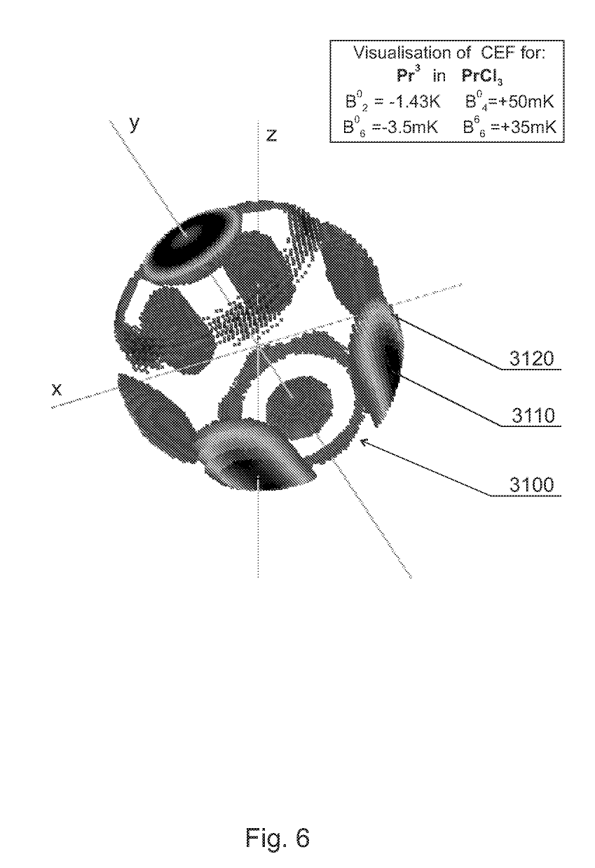

Thus, in one of the examples, discussed in connection with FIGS. 6-14, the chosen material is a material containing praseodymium ions Pr³⁺ in a PrCl₃ crystal, having a hexagonal structure, with the electron structure corresponding to a [Xe]4f² structure.

Because of scientific consistence concerning the correctness of use of the J number as a “good quantum number” of ions with an unclosed shell 4f and 5f, or ions of lanthanides and actinides, calculations in the |L,S,J,J_{z}> basis are assumed correct in their case. On the basis of fundamental laws of atomic physics, including rules for the construction of electron shells and subshells of an atom, and the Pauli exclusion principle, and in consequence the Hund's rules, the basic values of quantum numbers of the ground term amount to: L=5, S=1, J=4. These values are commonly acknowledged and available as a canon in tables and handbooks on atomic physics and chemistry. The values of these numbers are a starting point for the method of calculations of the electron structure states. Because of relations between quantum numbers, values of the J_{z} number are available, creating the basis or numbering the rows and columns of the CEF Hamiltonian matrix. For the discussed praseodymium ion Pr³⁺, they amount to: one L_{z}=|−4.0>,|−3.0>,|−2.0>,|−1.0>,|0.0>,|1.0>,|2.0>,|3.0>,|4.0>. Therefore, the order of the matrix to be created in the |L,S,J,J_{z}> basis amounts to: n=(2J+1)=9.

After obtaining a complete set of CEF parameters, defining the hexagonal field of the praseodymium ion environment in the PrCl₃ crystal, adopting values B⁰₂=−1.43K, B⁰₄=+50 mK, B⁰₆=−3.5 mK, B⁶₆=+35 mK, an interactive three-dimensional visualisation of such a field 3100 in Cartesian coordinates correlated with quantisation axes of operators of Hamiltonian components is obtained, presented in FIG. 6. In FIG. 6, various values of CEF are evident, starting from low values 3120 to maximum values 3110.

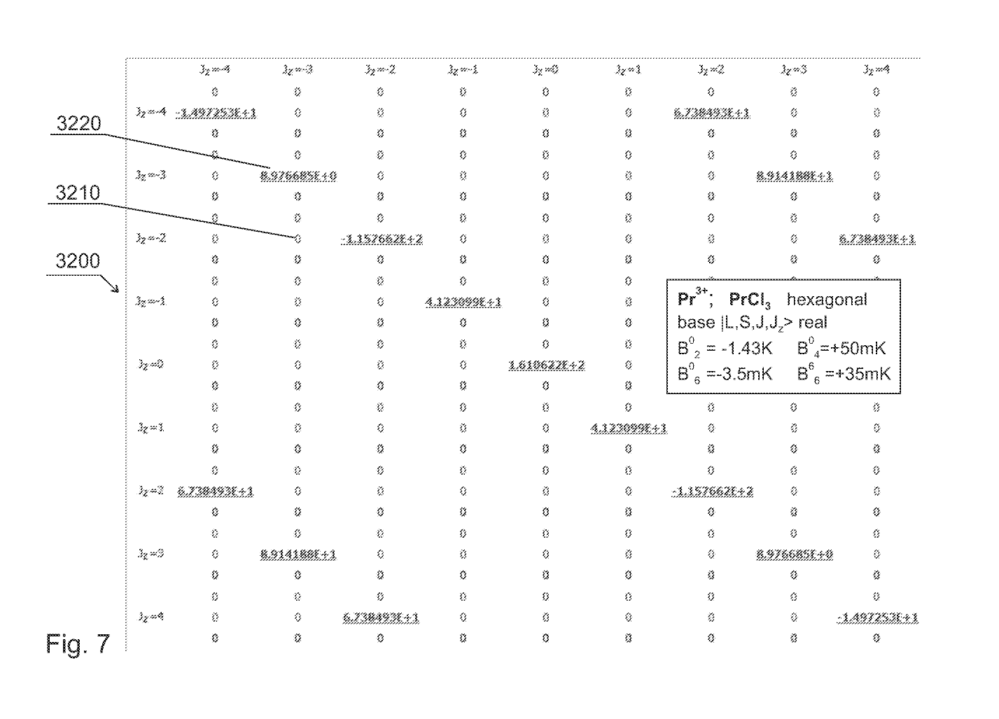

Starting the calculations of the influence of the so-defined CEF on the Pr³⁺ ion, the Hamiltonian matrix is generated on the basis of the defined Stevens operators. Numerical values of the filled matrix for the described praseodymium ion are shown in FIG. 7.

The Jacobi diagonalization procedure, according to step 2100 from FIG. 5D, brings the matrix 3200 to the form with the diagonal 3210 and values 3220, allowing for solving its eigenequation and obtaining the complete set of eigenvalues and eigenvectors, according to step 2200 from FIG. 5D.

The eigenvalues of the total energy operator, the so-called Hamiltonian, ‘EIGENVALUE’ and eigenfunctions ceigenfunction' corresponding to them and obtained from the solution of the Hamiltonian in the |L,S,J,J_{z}> basis are presented below, while the elements of the wave function basis are shown as abbreviated, omitting the constants. For Pr³⁺ in with L,S,J number, in general |L,S,J,J_{z}>=for Pr³⁺|5,1,4,J_{z}>=≡J_{z}>), the EIGENVALUE' values and eigenfunctions ‘eigenfunction’ corresponding to them, amount to:

eigenfunction[1]=+0.8941|−4.0>+0.4478|+2.0>

EIGENVALUE:E[1]=18.7767

eigenfunction[2]=+0.7071|−3.0>+0.7071|+3.0>

EIGENVALUE:E[2]=98.1186

eigenfunction[3]=+0.4478|−2.0>+0.8941|+4.0>

EIGENVALUE:E[3]=18.7767

eigenfunction[4]=+1|−1.0>

EIGENVALUE:E[4]=41.2310

eigenfunction[5]=+1|0.0>

EIGENVALUE:E[5]=161.0622

eigenfunction[6]=+1|+1.0>

EIGENVALUE:E[6]=41.2310

eigenfunction[7]=−0.4478|−4.0>+0.8941|+2.0>

EIGENVALUE:E[7]=−149.5155

eigenfunction[8]=−0.7071|−3.0>+0.7071|+3.0>

EIGENVALUE:E[8]=−80.1652

eigenfunction[9]=+0.8941|−2.0>−0.4478|+4.0>

EIGENVALUE:E[9]=−149.

Calculation of the expected values according to step 2200 from FIG. 5D allows for obtaining a complete set of information useful for simulation of material properties on the basis on knowledge of the structure of electron energy states. As a consequence of selection of real computational space, knowledge on the expected values of directional operators of components is obtained for two directional components x and z.

Sorting of normalised wave functions and calculation of the expected values in step 2300 from FIG. 5E lead to obtaining a complete structure of the Hamiltonian eigenstates:

| Energy level | En − Eo | Jx | Sx | Lx | m(x) |
|---|---|---|---|---|---|
| −149.517953 | 0.000000 | −0.030607 | −0.03673 | 0.00612 | −0.02449 |
| −149.516098 | 0.001856 | −0.007440 | −0.00893 | 0.00149 | −0.00595 |
| −80.163279 | 69.354675 | 0.023975 | 0.02877 | −0.00480 | 0.01918 |
| 18.774289 | 168.292242 | −0.030718 | −0.03686 | 0.00614 | −0.02457 |
| 18.775766 | 168.293719 | −0.012284 | −0.01474 | 0.00246 | −0.00983 |
| 41.230363 | 190.748316 | −0.007819 | −0.00938 | 0.00156 | −0.00626 |
| 41.232504 | 190.750457 | 0.018916 | 0.02270 | −0.00378 | 0.01513 |
| 98.120109 | 247.638063 | 0.019243 | 0.02309 | −0.00385 | 0.01539 |
| 161.064298 | 310.582251 | 0.026735 | 0.03208 | −0.00535 | 0.02139 |

| Energy level | En − Eo | Jz | Sz | Lz | m(z) |
|---|---|---|---|---|---|
| −149.515502 | 0.000000 | −0.796762 | −0.95611 | 0.15935 | −0.63741 |
| −149.515502 | 0.000000 | 0.796762 | 0.95611 | −0.15935 | 0.63741 |
| −80.165199 | 69.350303 | 0.000000 | 0.00000 | −0.00000 | 0.00000 |
| 18.776750 | 168.292251 | 2.796762 | 3.35611 | −0.55935 | 2.23741 |
| 18.776750 | 168.292251 | −2.796762 | −3.35611 | 0.55935 | −2.23741 |
| 41.230989 | 190.746491 | 1.000000 | 1.20000 | −0.20000 | 0.80000 |
| 41.230989 | 190.746491 | −1.000000 | −1.20000 | 0.20000 | −0.80000 |
| 98.118568 | 247.634070 | −0.000000 | −0.00000 | 0.00000 | −0.00000 |
| 161.062157 | 310.577658 | 0.000000 | 0.00000 | 0.00000 | 0.00000 |

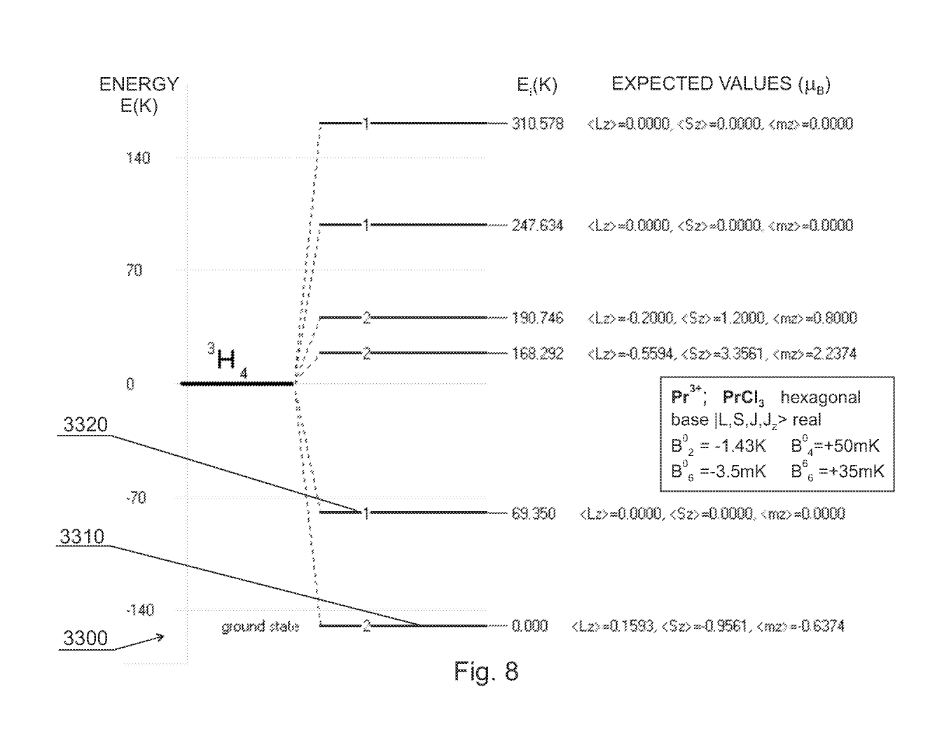

The calculated values are presented in FIG. 8 in the diagram 3300 of energy states, in which the ground state 3310 and the next state 3320 are marked.

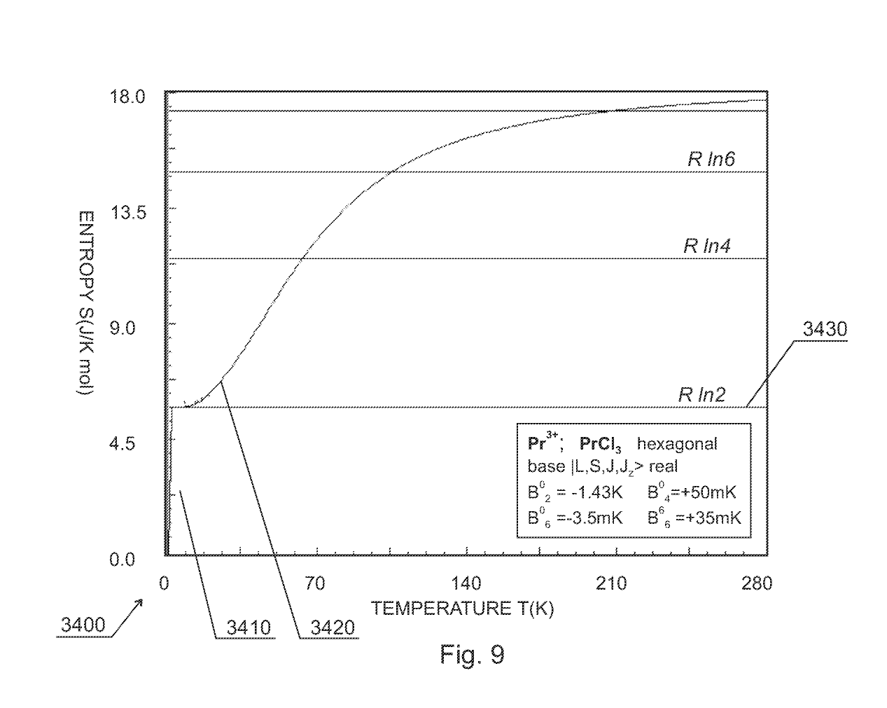

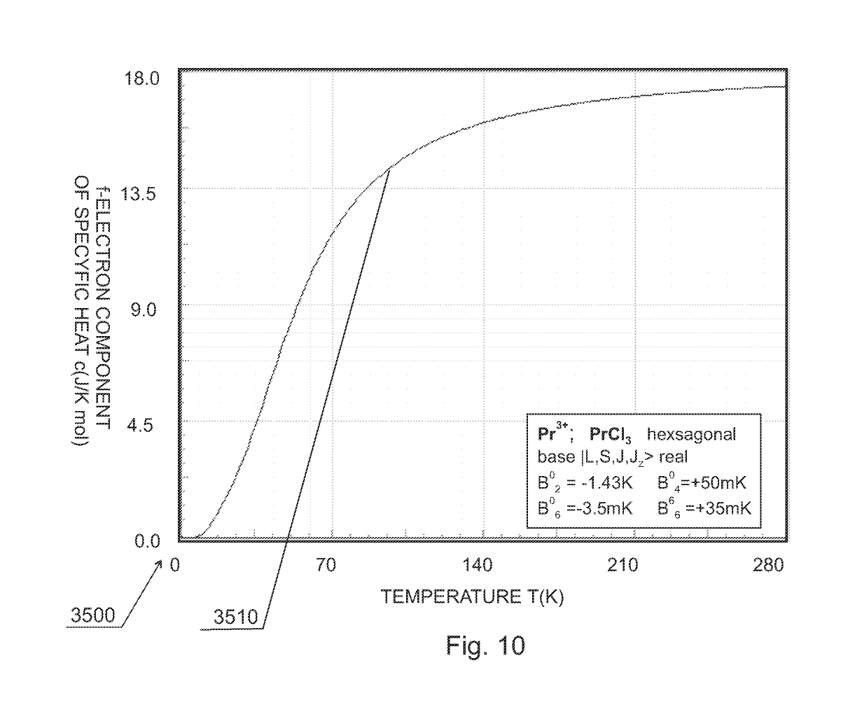

To define the influence of temperature on the properties of the ion, numerical summations are carried out in order to determine the sum of states Z(T), and calculations of filling of the individual states (populations) vs. temperature according to step 2400 from FIG. 5E for four parallel states are carried out. On the basis of calculations based on such statistics, results pertaining to the statistical behaviour of a large number of such ions in identical thermodynamic conditions were obtained. The operations were carried out according to formulas presented for step 2500 from FIG. 5E, by numerical integrations and differentiations directly during the visualisation or saving the results to a file according to steps 2700 and 2800 from FIG. 5E. FIGS. 6 and 7 present the results of such calculations for the calculated structure of electron states of the Pr³⁺ ion under the influence of a hexagonal CEF shown in FIG. 6. The temperature dependency 3510 of the specific heat component originating from the Pr³⁺ ions is shown in FIG. 10 in plot 3500, while the dependency of entropy in two areas 3410 and 3420 vs. temperature is presented in FIG. 9 in plot 3400. In FIG. 9, horizontal lines 3430 are plotted indicating the relation of the calculated thermodynamic entropy originating from 4f electrons with the statistical entropy defined provisionally as a product of universal gas constant R (R=8.31 J/mole) and natural logarithm of the number of filled states.

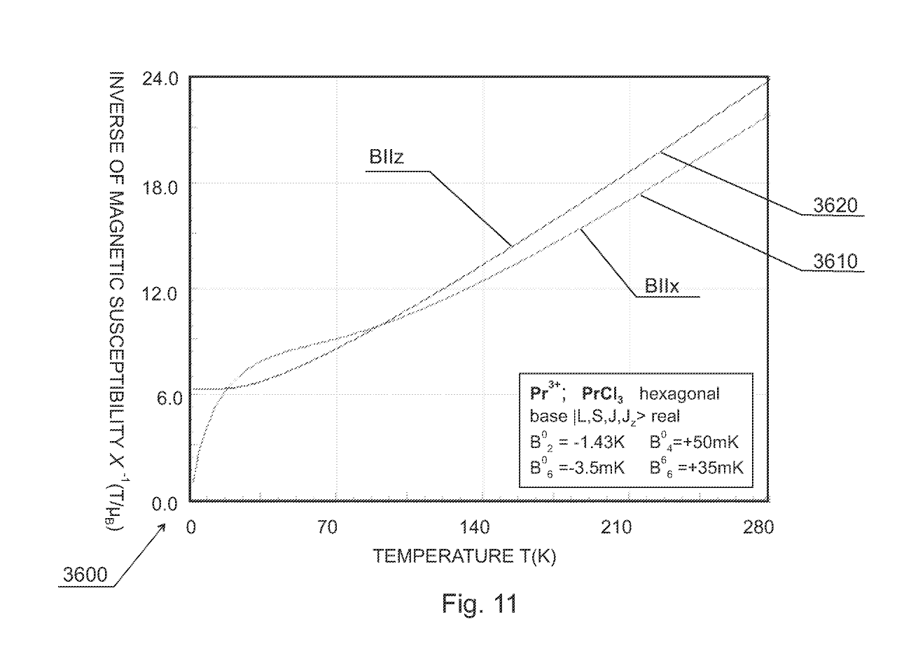

The calculated expected values of operators: Jₓ, Sₓ, Lₓ and J_{z}, S_{z}, L_{z} in eigenstates, allow for calculating the expected directional components of the expected values 3610, 3620 of magnetic moments of the individual i^{th} states of electron structure <mⁱₓ> and <mⁱ_{z}>. This fact, in connection with knowledge on population of states vs. temperature, according to Boltzmann statistics, allows for calculating the directional magnetic susceptibility for possible simulation directions x and z. For convenience, in order to determine the so-called effective moment easily, the procedure of optimisation enables a visualisation of magnetic susceptibility in the inverse form, which is presented in FIG. 11 in the diagram 3600.

Lack of possibility to obtain information on y components during calculations in matrices based on real elements prevents construction of complete data on the spatial magnetic properties of a material. Realisation of calculations based on calculus of complex matrices allows for solving this problem. Moreover, it is more preferable to carry out the calculations in the full |L,S,L_{z},S_{z}> basis, in spite of the theoretical permissibility to use the |L,S,J,J_{z}> basis for ions with an unclosed 4f and 5f shell, due to a more complete picture of the structure of states.

In case of the |L,S,L_{z},S_{z}> basis, the calculations are more time-consuming, by engaging larger hardware resources of the computing unit, but, from the theoretical point of view, they always ensure better results. Adoption of the |L,S,L_{z},S_{z}> basis provides an exemption from the necessity to adopt the assumption of preservation of the quantum number J. Therefore, as a consequence of the first two Hund's rules, the basic values of quantum numbers amount to L=5, S=1, respectively. The values of these numbers are a starting point for the method of calculations of the electron structure states. Because of the relations between quantum numbers, now their pairs |L_{z},S_{z}>, and not |J_{z}> as before, are creating the bases, or numbering rows and columns of the CEF Hamiltonian matrix. In case of the Pr³⁺ ion being described, the states creating the basis for the calculations carried out are:

|L,S,L_{z},S_{z}>=|L_{z},S_{z}>:|+5,+1>,|+5,0>,|+5,−1>,|+4,+1>,|+4,0>,

|+4,−1>,|+3,+1>,|+3,0>,|+3,−1>,|+2,+1>,|+2,0>,|+2,−1>,|+1,+1>,|+1,0>,

|+1,−1>,|+0,+1>,|+0,0>,|+0,−1>,|1−1,+1>,1|−1,0>,|−1,−1>,|−2,+1>,|−2,0>,

|−2,−1>,|−3,+1>,|−3,0>,|−3,−1>,|−4,+1>,|−4,0>,|−4,−1>,|−5,+1>,|−5,0>,|−5,−1>.

Therefore, the order of the matrix to be created in the |L,S,L_{z},S_{z}> basis amounts to: n=(2L+1) (2S+1)=33.

After conversion of the field coefficients between the bases on the grounds of a database of transfer coefficients implemented in the tool, according to the relation between steps 800 and 540, a defined hexagonal CEF of the environment of the praseodymium ion in the PrCl₃ crystal is obtained with coefficients additionally containing information on the spin-orbit coupling:

B⁰₂=−1.43K, B⁰₄=+50 mK, B⁰₆=−3.5 mK, B⁶₆=+35 mK, λₛ₋ₒ=−650K

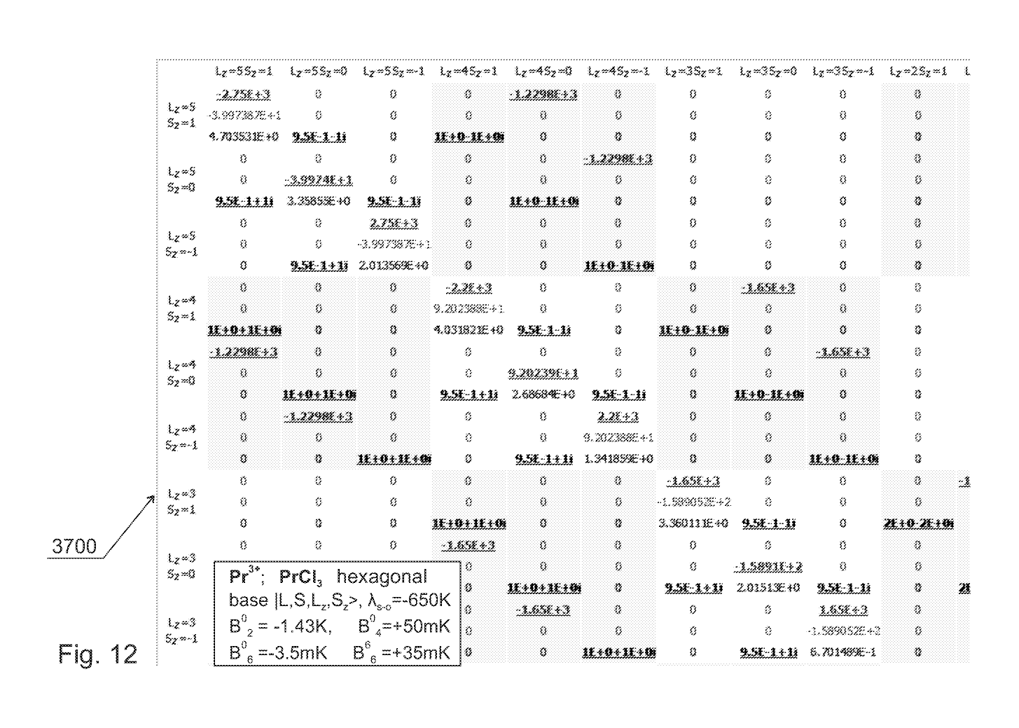

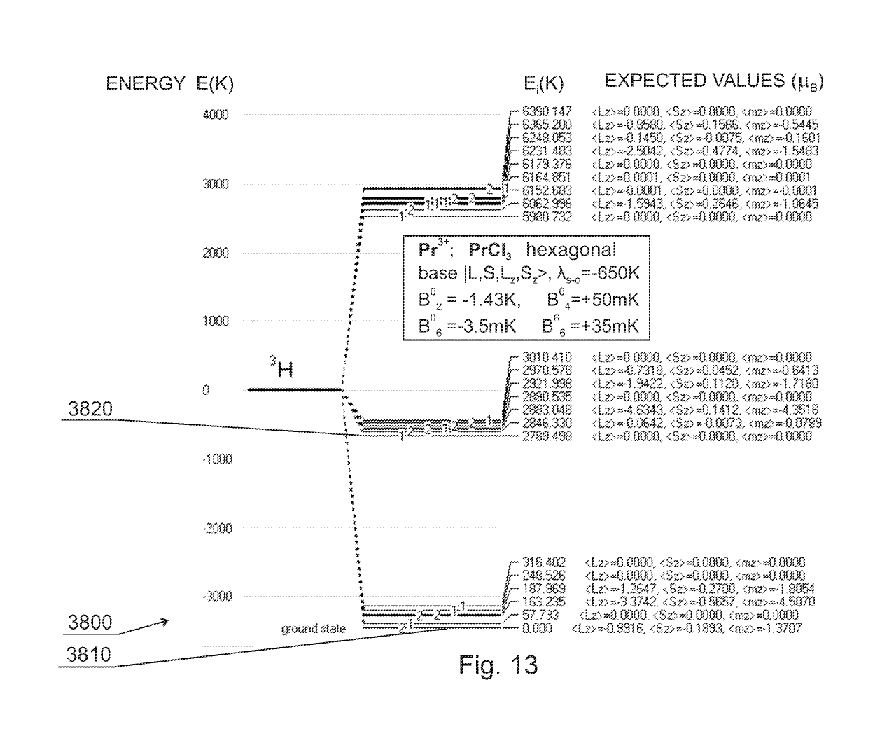

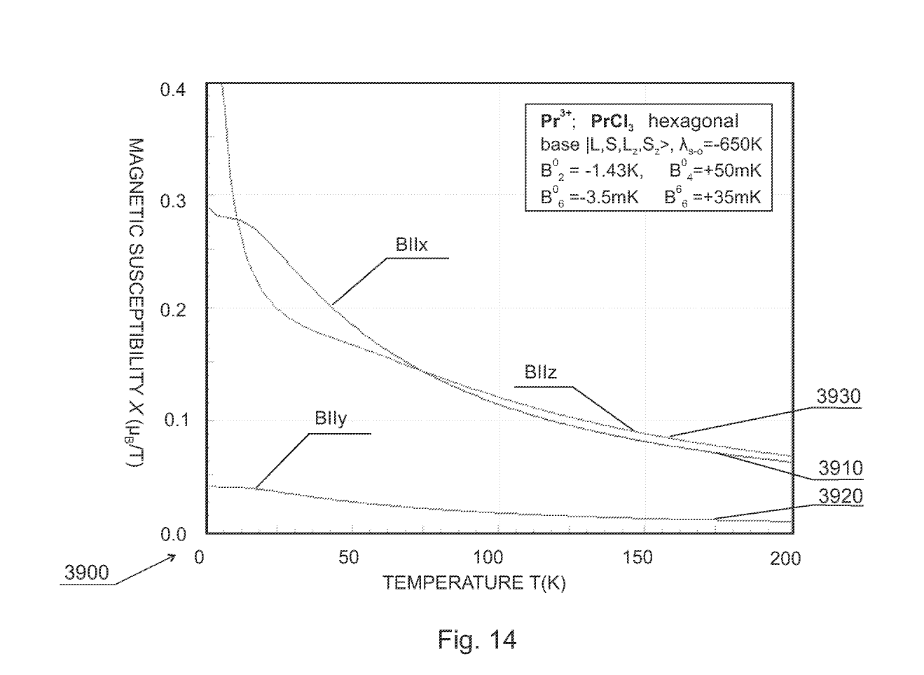

A fragment of the Hamiltonian matrix 3700 constructed in the space spanned across a body of complex numbers is shown in FIG. 12. A consequence of solving the Hamiltonian eigenequation described by the matrix from FIG. 12 is a structure 3800 of states shown in FIG. 13 with marked ground state 3810 and group 3820 of states. Analogically as above, directional magnetic susceptibility for possible simulation of directions z, x and y is calculated. A visualisation 3900 of the course of magnetic susceptibility vs. temperature, for all spatial components 3910, 3920, 3930, is presented in FIG. 14. One may see there a dramatically different course of the magnetic susceptibility curve in the field applied along the y axis. Such calculations enable construction of complete data on the spatial magnetic properties of a material.

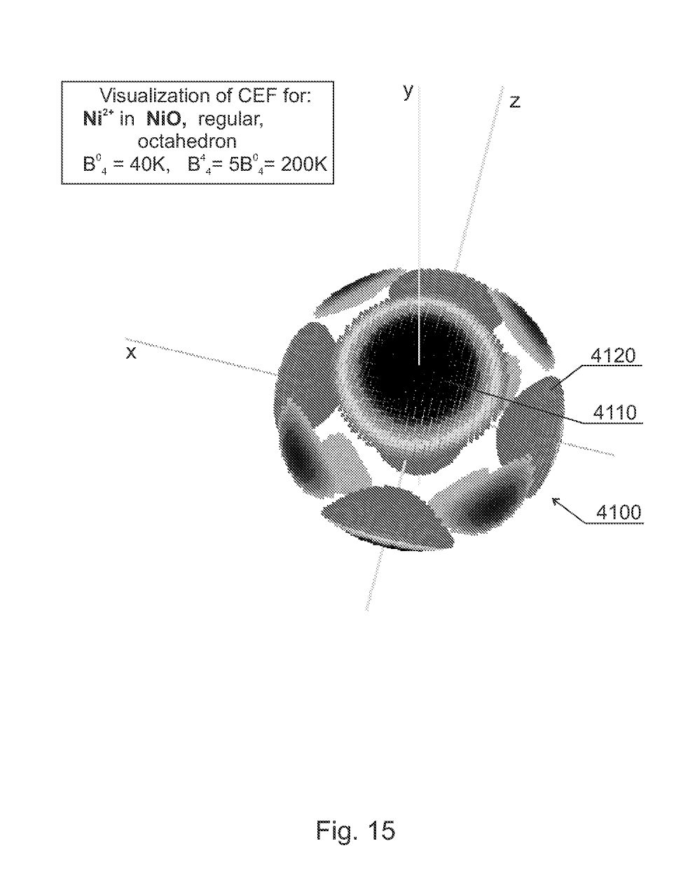

In another example, discussed in connection with FIG. 15-24, the chosen material is a material containing an Ni²⁺ ion in an oxide complex NiO, having a regular structure of the NaCl type, a coordination octahedron and an electron structure corresponding to the [Ar]3d⁸ structure.

On the basis of fundamental laws of atomic physics and in consequence of the Hund's rules, the basic values of quantum numbers of the ground term amount to: L=3, S=1. The values of these numbers are a starting point for the method of calculations of the electron structure states. Because of the relations between quantum numbers, the available values of L_{z}, and S_{z} numbers, creating the basis for the calculations, are:

|L,S,L_{z},S_{z}>=|L_{z},S_{z}>:|+3,+1>,|+3,0>,|+3,−1>,|+2,+1>,|+2,0>,

|+2,−1>,|+1,+1>,|+1,0>,|+1,−1>,|+0,+1>,|+0,0>,|+0,−1>,|−1,+1>,

|−1,0>,|−1,−1>,|−2,+1>,|−2,0>,|−2,−1>,|3,+1>,|−3,0>,|−3,−1>.

Automatically, together with selection of the basis according to step 500, a constant of the spin-orbit coupling is introduced as for a free ion: λₛ₋ₒ=41 meV, and its value is left unchanged for further calculations carried out according to step 660.

After obtaining CEF parameters, evaluated as: B⁰₄=2 meV, B⁴₄=10 meV, an interactive, three-dimensional visualisation of such a field 4100 is obtained in Cartesian coordinates correlated with the quantisation axes of operators of Hamiltonian components presented in FIG. 12 with dark areas 4110 and bright areas 4120.

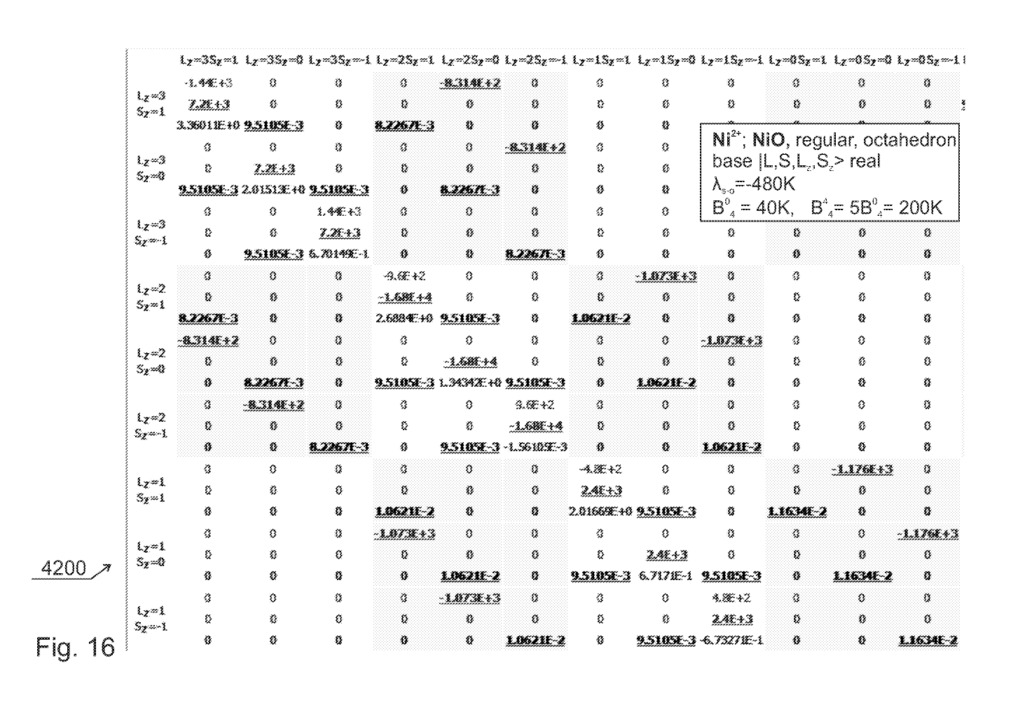

The next step consists in generation of the Hamiltonian matrix, on the basis of the defined Stevens operators, while the apparent form of the matrix elements d⁸ is the same as in the matrix d², and only the signs at the values of λₛ₋ₒ are changed to opposites (+/−). The numerical values of a sector of the filled matrix 4200 are presented in FIG. 16. For promptitude of the demonstrative calculations, matrices with real elements are being selected, posing no large limitation in case of such a highly symmetrical system.

The Jacobi diagonalization procedure according to step 1550 brings the matrix to a form allowing for solving its eigenequation and obtaining the complete set of eigenvalues and eigenvectors according to step 2200.

The calculated values of energy ‘EIGENVALUE’, eigenfunctions ‘eigenfunction’ |L,S,L_{z},S_{z}> abbreviated as |L_{z},S_{z}> have the following form:

EIGENVALUE:E[8]=7641.1939

eigenfunction[9]=+0.5192|+3,+1.0>−0.48|+1,−1.0>+0.48|−1,+1.0>−0.5192−3,−1.0>

EIGENVALUE:E[9]=7641.1939

eigenfunction[10]=+0.5637|+2,−1.0>−0.5198|+1,0.0>−0.0569|0,+1.0>+0.4285|−2,−1.0>+0.4746|−3,0.0>

EIGENVALUE:E[10]=−2464.5964

eigenfunction[11]=+0.4564|+3,+1.0>+0.3536|+1,−1.0>+0.5774|0,0.0>+0.3536|−1,+1.0>+0.4564|−3,−1.0>

EIGENVALUE:E[11]=6840.0000

eigenfunction[12]=+0.4746|+3,0.0>+0.4285|+2,+1.0>−0.0569|0,−1.0>−0.5198|−1,0.0>+0.5637|−2,+1.0>

EIGENVALUE:E[12]=−2464.5964

eigenfunction[13]=+0.48|+3,+1.0>+0.5192|+1,−1.0>−0.5192|−1,+1.0>−0.48|−3,−1.0>

EIGENVALUE:E[13]=−3081.1939

eigenfunction[14]−−0.3827|+3,0.0>+0.4981|+2,+1.0>+0.0615|0,−1.0>+0.5946|−1,0.0>+0.4981|−2,+1.0>

EIGENVALUE:E[14]−−3081.1939

eigenfunction[15]=−0.3847|+3,−1.0>+0.0676|+2,0.0>−0.5895|+1,+1.0>+0.5895|−1,−1.0>−0.0676|−2,0.0>+0.3847|−3,+1.0>

EIGENVALUE:E[15]=−2464.5964

eigenfunction[16]=+0.0433|+3,0.0>+0.7517|+2,+1.0>−0.0024|0,−1.0>−0.0519|−1,0.0>−0.6561|−2,+1.0>

EIGENVALUE:E[16]=−16690.3836

eigenfunction[17]=−0.1748|+3,−1.0>+0.5724|+2,0.0>+0.3766|+1,+1.0>+0.3766|−1,−1.0>+0.5724|−2,0.0>−0.1748|−3,+1.0>

EIGENVALUE:E[17]=−3212.2460

eigenfunction[18]=+0.4981|+2,−1.0>+0.5946|+1,0.0>+0.0615|0,+1.0>+0.4981|−2,−1.0>−0.3827|−3,0.0>

EIGENVALUE:E[18]=−3081.1939

eigenfunction[19]=|0.0395|+3,1.0>+0.7039|+2,0.0>+0.0549|+1,+1.0>−0.0549|1,1.0>0.7039|2,0.0>0.03951|3,+1.0>

EIGENVALUE:E[19]=−16690.3836

eigenfunction[20]=−0.6561|+2,−1.0>−0.0519|+1,0.0>−0.0024|0,+1.0>+0.7517|−2,−1.0>+0.0433|−3,0.0>

EIGENVALUE:E[20]=−16690.3836

eigenfunction[21]=−0.4715|+3,+1.0>+0.5215|+1,−1.0>+0.106710,0.0>+0.5215|−1,+1.0>−0.4715|−3,−1.0>

EIGENVALUE:E[21]=−3212.2460

Calculation of the expected values according to step 2200 from FIG. 5D allows for obtaining a complete set of information useful for simulation of material properties on the basis on the structure of states. As a consequence of selection of real computational space, knowledge on the expected values of directional operators of moment components will be obtained for two directional components x and z.

Sorting of normalised wave functions and calculation of the expected values in step 2300 from FIG. 5E lead to obtaining a complete structure of the Hamiltonian eigenstates:

| Energy level | En − Eo | Jx | Sx | Lx | m(x) |
|---|---|---|---|---|---|
| −16690.601145 | 0.000000 | −1.267532 | −0.99541 | −0.27212 | −2.26526 |
| −16690.383555 | 0.217590 | −0.000039 | −0.00000 | −0.00004 | −0.00004 |
| −16690.165965 | 0.435180 | 1.267455 | 0.99541 | 0.27204 | 2.26518 |
| −3212.246464 | 13478.354681 | −0.007063 | −0.00385 | −0.00321 | −0.01092 |
| −3212.245986 | 13478.355159 | −0.000118 | −0.00017 | 0.00005 | −0.00029 |
| −3081.298277 | 13609.302868 | −0.578373 | −0.49255 | −0.08582 | −1.07207 |
| −3081.193407 | 13609.407738 | 0.006961 | 0.00385 | 0.00311 | 0.01082 |
| −3081.089535 | 13609.511609 | 0.578308 | 0.49231 | 0.08600 | 1.07176 |
| −2464.705362 | 14225.895783 | −0.635400 | −0.49797 | −0.13743 | −1.13453 |
| −2464.596520 | 14226.004624 | −0.000956 | −0.00116 | 0.00020 | −0.00212 |
| −2464.487443 | 14226.113702 | 0.635449 | 0.49822 | 0.13723 | 1.13482 |
| −2279.999877 | 14410.601268 | 0.001035 | 0.00133 | −0.00029 | 0.00236 |
| 6839.999932 | 23530.601077 | −0.001070 | −0.00048 | −0.00059 | −0.00155 |
| 7641.156682 | 24331.757827 | 0.421426 | −0.49253 | 0.91396 | −0.07225 |
| 7641.193953 | 24331.795098 | 0.000952 | 0.00037 | 0.00059 | 0.00132 |
| 7641.231082 | 24331.832227 | −0.421892 | 0.49232 | −0.91422 | 0.07158 |
| 9074.920835 | 25765.521980 | 0.097361 | −0.49340 | 0.59076 | −0.39719 |
| 9074.979921 | 25765.581065 | 0.000951 | −0.00115 | 0.00210 | −0.00020 |
| 9075.039127 | 25765.640272 | −0.096803 | 0.49361 | −0.59042 | 0.39796 |
| 9212.245985 | 25902.847130 | 0.000220 | 0.00011 | 0.00011 | 0.00033 |
| 9212.246018 | 25902.847162 | −0.000874 | 0.00115 | −0.00202 | 0.00027 |

| Energy level | En − Eo | Jz | Sz | Lz | m(z) |
|---|---|---|---|---|---|
| −16690.383554 | 0.000000 | 1.267493 | 0.99541 | 0.27208 | 2.26522 |
| −16690.383554 | 0.000000 | 0.000000 | 0.00000 | 0.00000 | 0.00000 |
| −16690.383554 | 0.000000 | −1.267493 | −0.99541 | −0.27208 | −2.26522 |
| −3212.245971 | 13478.137583 | −0.000000 | −0.00000 | −0.00000 | −0.00000 |
| −3212.245971 | 13478.137583 | 0.000000 | 0.00000 | 0.00000 | 0.00000 |
| −3081.193897 | 13609.189657 | 0.578341 | 0.49243 | 0.08591 | 1.07191 |
| −3081.193897 | 13609.189657 | 0.000000 | −0.00000 | 0.00000 | 0.00000 |
| −3081.193897 | 13609.189657 | −0.578341 | −0.49243 | −0.08591 | −1.07191 |
| −2464.596411 | 14225.787142 | 0.635425 | 0.49810 | 0.13733 | 1.13468 |
| −2464.596411 | 14225.787142 | −0.635425 | −0.49810 | −0.13733 | −1.13468 |
| −2464.596411 | 14225.787142 | −0.000000 | 0.00000 | −0.00000 | −0.00000 |
| −2280.000000 | 14410.383554 | −0.000000 | −0.00000 | 0.00000 | −0.00000 |
| 6840.000000 | 23530.383554 | −0.000000 | −0.00000 | −0.00000 | −0.00000 |
| 7641.193897 | 24331.577450 | −0.421659 | 0.49243 | −0.91409 | 0.07191 |
| 7641.193897 | 24331.577450 | 0.000000 | 0.00000 | 0.00000 | 0.00000 |
| 7641.193897 | 24331.577450 | 0.421659 | −0.49243 | 0.91409 | −0.07191 |
| 9074.979965 | 25765.363518 | −0.097082 | 0.49351 | −0.59059 | 0.39757 |
| 9074.979965 | 25765.363518 | 0.000000 | 0.00000 | 0.00000 | 0.00000 |
| 9074.979965 | 25765.363518 | 0.097082 | −0.49351 | 0.59059 | −0.39757 |
| 9212.245971 | 25902.629524 | −0.000000 | 0.00000 | −0.00000 | −0.00000 |
| 9212.245971 | 25902.629524 | 0.000000 | −0.00000 | 0.00000 | 0.00000 |

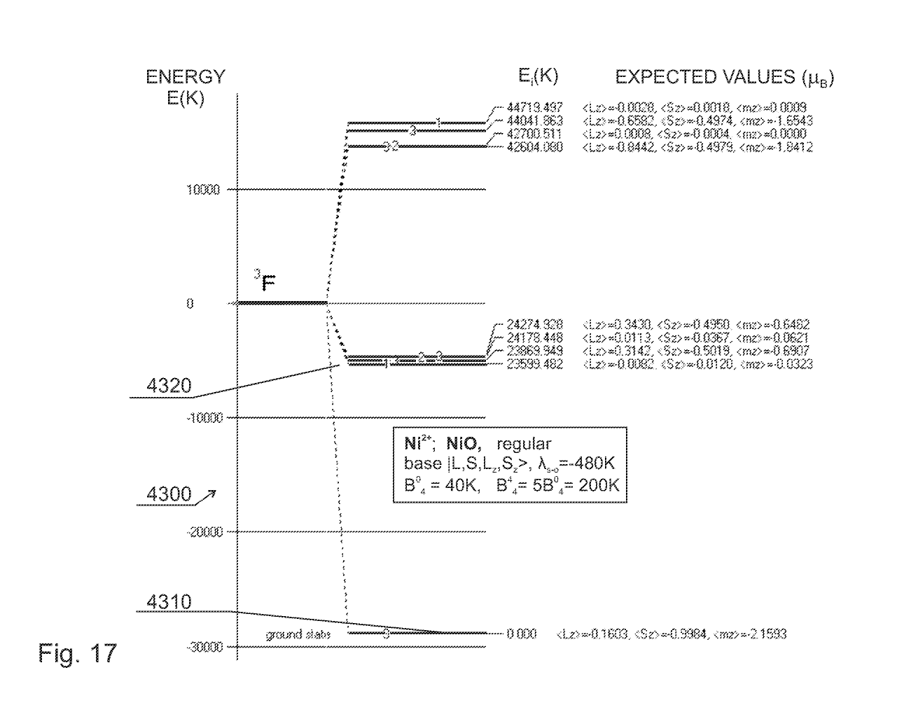

The calculated values may be visualised directly in the diagram 4300 of energy states presented in FIG. 17 with marked ground state 4310 and group 4320 of the next states.

The next step consists in calculation of the sum of states and populations of the individual states vs. temperature according to step 2500 from FIG. 5E. After the calculations, results pertaining to the statistical behaviour of a large number of such ions in identical thermodynamic conditions are obtained. The operations are carried out according to formulas presented earlier for step 2200 from FIG. 5D, by numerical integrations and differentiations directly during the visualisation or saving the results to a file in steps 2700 and 2800 from FIG. 5E.

In the result of statistical calculations, it is evident that only a minimal contribution to specific heat originating from d electrons exists, because of a triplet ground state highly separated energetically. Knowledge on thermodynamic functions allows for simulating the directional components of magnetic susceptibility vs. temperature.

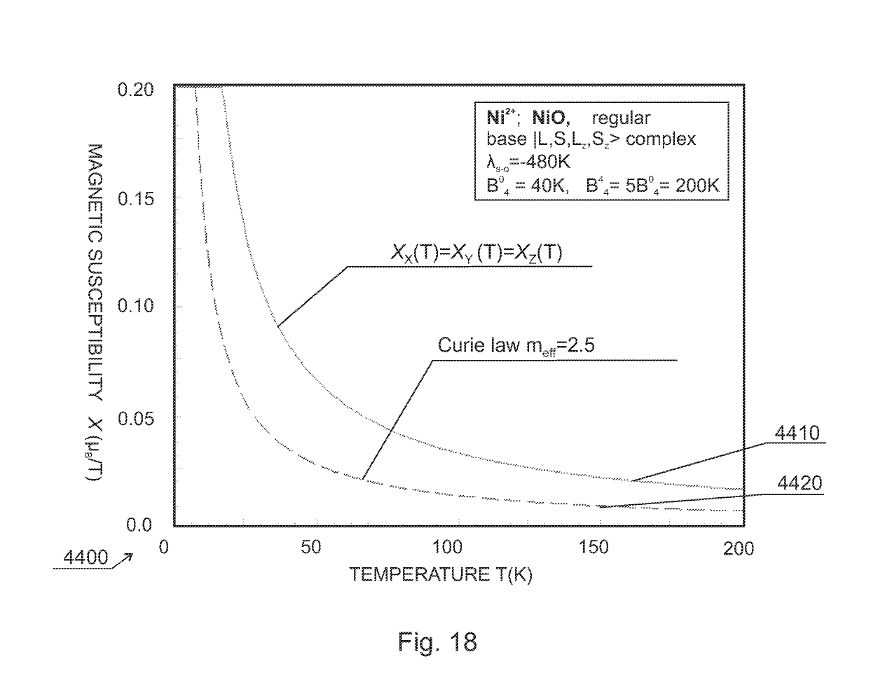

In this case, both calculated directions are equivalent, as one may expect introducing an octahedral field with a regular symmetry. The result of calculations of magnetic susceptibility 4410 measured along the field parallel to the x and z axes is presented in FIG. 18 in the diagram 4400. The simulation procedure allows for comparing the obtained result with curve 4420 representing the Curie law with a defined value of the effective moment. In this case, the value of the effective number of Bohr magnetons was assumed as 2.5.

A crystal field with a lower symmetry is able to split the directional components, determining an easy magnetisation axis. The calculations using the defined tools allow for simulating the effect of deformation of the oxygen octahedron coordinating the Ni+² ion.

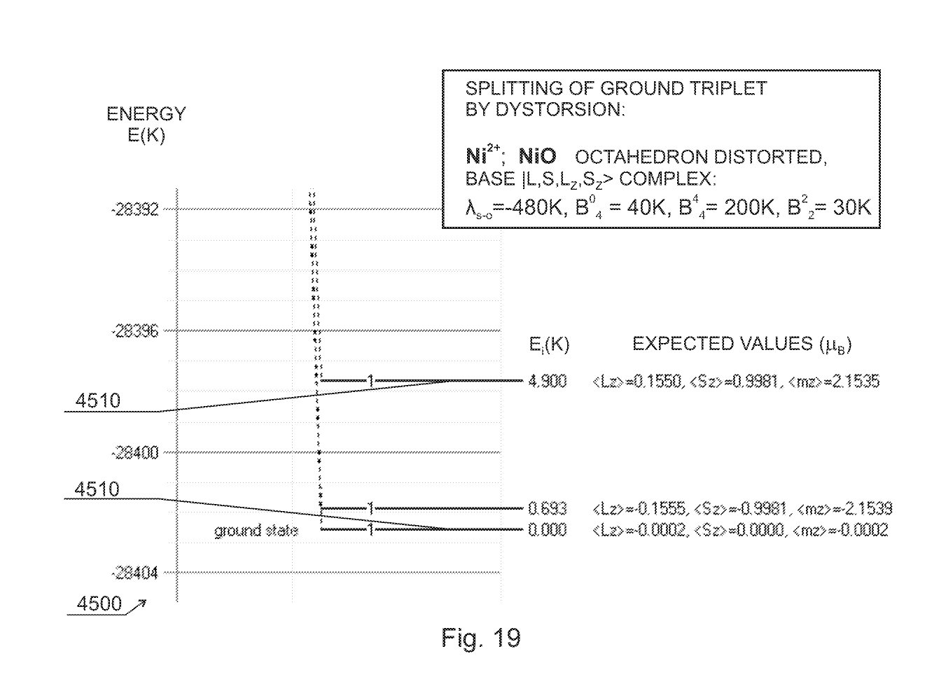

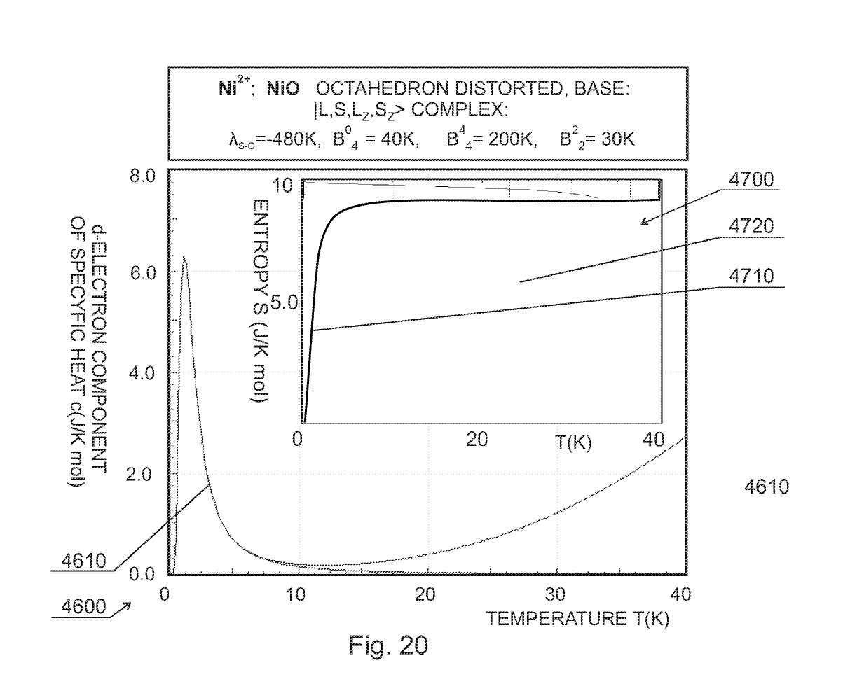

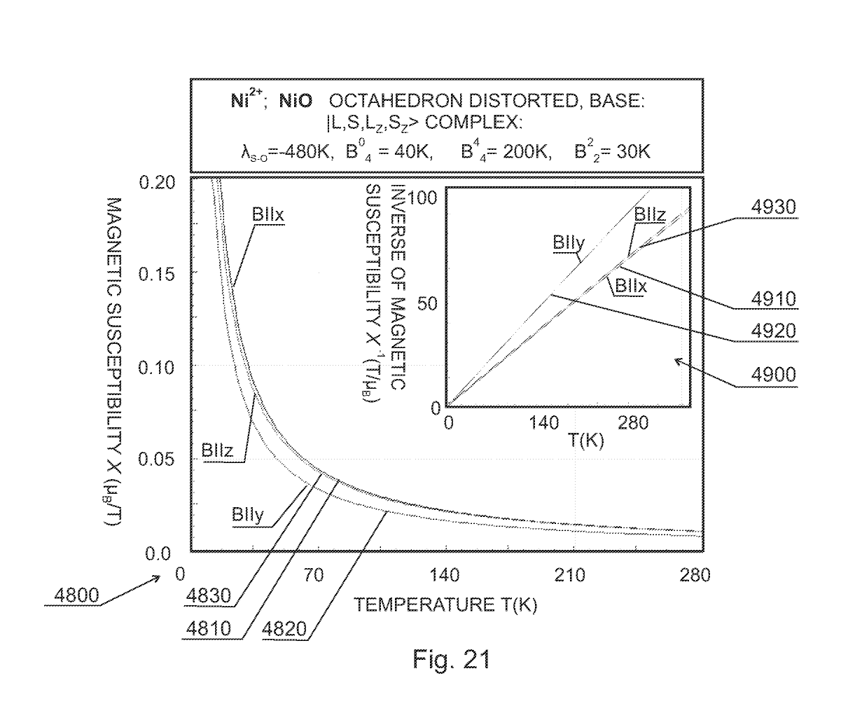

In fact, such deformations may be of a structural origin or they may result from the influence of external forces. They may have a natural origin as a consequence of Jahn-Teller effect, as well as a consequence of induced external conditions. Such a simulation leads to results with properties directionally diffused, which may be seen in full calculations in a complex space. The simulation of deformation of the coordination octahedron of the Ni²⁺ ion is realised by the introduction of additional components of the quadrupole moment described with the O²₂ operator. The result of exemplary calculations leads to a splitting of the ground triplet into singlet components 4510, 4520 presented in FIG. 19 in the diagram 4500. Such a splitting of the state 4620, 4630 is revealed as a maximum 4610 in the specific heat c(T) course shown in FIG. 20 in the diagram 4600 and the course 4710 of entropy with a straight line 4720 marked in the diagram 4700, and magnetic susceptibility for all spatial components 4810, 4820, 4830 presented in FIG. 21 in the diagram 4800, as well as magnetic susceptibility 4900 in the inverse form 4910, 4920, 4930, and it allows for modelling, anticipating and describing the properties of the material in the function of achievable structural modifications.

While the technical concept presented herein has been depicted, described, and has been defined with reference to particular preferred embodiments, such references and examples of implementation in the foregoing specification do not imply any limitation on the concept. It will, however, be evident that various modifications and changes may be made thereto without departing from the broader scope of the technical concept. The presented preferred embodiments are exemplary only, and are not exhaustive of the scope of the technical concept presented herein. Accordingly, the scope of protection is not limited to the preferred embodiments described in the specification, but is only limited by the claims that follow.

1. Optimisation of a method for determining material properties at finding materials having defined properties during which a chosen material, containing elements chosen from Periodic Table having at least one kind of ions with electron subshell containing a number of electrons starting from 1 to value adequate to situation called closed electron subshell is selected based on information available in the state of art, the optimization comprising
defining at least one component element of the chosen material;
determining an oxidation state of chosen atoms of the component element being selected in the chosen material to define their electron configuration;
carrying out calculations of a spin magnetic moment S and optionally a total magnetic moment J corresponding to a ground state of selected ions for selected ions of the component element after determining values of quantum numbers of an orbital magnetic moment L, to find a complete set of Crystal Electric Field (CEF) coefficients, defined by Stevens coefficients defining value of influence of electric multipoles interacting with an unclosed electronic subshell of ion and having a form of B^{m}ₙ, expressed in energy units and defining an immediate charge environment of the selected ions in a crystal lattice by calculation of Stevens coefficients having the form of B^{m}ₙ;
generating a total energy operator called Hamiltonian with matrix elements containing Stevens operators multiplied by the defined Stevens coefficients B^{m}ₙ(H_{CEF}=ΣB^{m}ₙO^{m}ₙ), based on the complete set of Crystal Electric Field (CEF) parameters and having the form of B^{m}ₙ and (x, y, z) or (x, z) components of operators of magnetic field potential;
projecting operators of an orbital magnetic moment, a spin magnetic moment and a total magnetic moment, and optionally components of operators of the a spin-orbit coupling;
carrying out operations on the total energy operator as a Hamiltonian matrix;
creating a model of an ideal material containing the selected ions, the selected ions being spatially identically oriented and not interacting with each other but interacting with an external magnetic field and an external electric field with a calculated structure of energy states together with their spectral properties, and being subjected to classical Boltzmann statistics, and having the directional (x, y, z) or (x, z) components of magnetic properties calculated based on the model of the ideal material defining calorimetric, electron and magnetic properties in a form of temperature dependencies of a material containing ions in a defined environment of the crystal field (CEF); and
verifying properties of the ideal material with the properties of a real material when the properties of the material obtained from calculations correspond to the properties of the material being searched for.

2. The optimisation of the method according to claim 1, wherein the value of the quantum numbers of the orbital magnetic moment L, the spin magnetic moment S and optionally the total magnetic moment J, corresponding to the ground state of electron configuration of the selected ions is determined based on Hund's rules.

3. The optimisation of the method according to claim 1, wherein calculation of the Stevens coefficients with the form of B^{m}ₙ is carried out after choosing one of calculation methods and determining a computation space, choosing a basis for calculations and determining values of constants.

4. The optimisation of the method according to claim 3, wherein calculations of the Stevens coefficients with the form of B^{m}ₙ are carried out using a Point Charge Model Approximation (PCM) or using an interactive three-dimensional (3D) visualisation of component multipoles of the external electric field and their superpositions defined as the crystal field (CEF) or by a conversion of CEF coefficients (A^{m}ₙ−>B^{m}ₙ) from known results of other calculations for systems isostructural with the one being calculated, but containing other ions.

5. The optimisation of the method according to claim 4, wherein results of calculations of the Stevens coefficients with the form of B^{m}ₙ are harmonised by comparing obtained results using the Point Charge Model Approximation (PCM) or the interactive visualisation of the crystal field (CEF) in 3D, or by the conversion of crystal field (CEF) coefficients (A^{m}ₙ−>B^{m}ₙ) from results of other calculations for systems isostructural with the one being calculated, but containing other ions.

6. The optimisation of the method according to claim 1, wherein all operations leading to calculation of the structure of states of the selected ions in the defined environment in a crystal lattice are carried out after choosing a computation space from a vector space spanned across a body of real numbers and space spanned across a body of complex numbers, and choosing a basis for construction of the Hamiltonian matrix or the total energy operator.

7. The optimisation of the method according to claim 6, wherein after choosing (630) a space of real numbers and carrying out calculations in |L,S,J,J_{z}> basis, while generating a matrix containing products of the matrix elements of the Stevens operators and the defined Stevens coefficients (B^{m}ₙ, O^{m}ₙ) and operators of the directional components (x, z) of the external magnetic field, at first, an empty matrix is created with rows and columns numbered with values of |J_{z}>, the matrix being filled with products of the matrix elements of the Stevens operators and the defined Stevens coefficients (B^{m}ₙ, O^{m}ₙ) and the component operators (x, z) of the external magnetic field, and after choosing the space of real numbers and carrying out the calculations with |L, S, L_{z}, S_{z}> basis, while generating the matrix containing products of the matrix elements of the Stevens operators and the defined Stevens coefficients (B^{m}ₙ, O^{m}ₙ) and the component operators (x, z) of the external magnetic field, at first, an empty matrix is created with rows and columns numbered with |L_{z}, S_{z}> combinations, which, as an initially prepared Hamiltonian matrix, is filled with components of the Stevens operators (B^{m}ₙ, O^{m}ₙ), the component operators (x, z) of the external magnetic field and components of the spin-orbit coupling operator.

8. The optimisation of the method according to claim 6, wherein after choosing the space of real numbers and complex numbers, and carrying out the calculations in the |L,S,J,J_{z}> basis, while generating the matrix containing fillings with the products of the matrix elements of Stevens operators and the defined Stevens coefficients (B^{m}ₙ, O^{m}ₙ), and the component operators (x, y, z) of the external magnetic field, at first, an empty matrix is created with rows and columns numbered with values of |J_{z}>, the matrix being filled with products of the matrix elements of the Stevens operators and the defined Stevens coefficients (B^{m}ₙ, O^{m}ₙ), the total moment projection operators and the component operators (x, y, z) of the external magnetic field, and after choosing the space of complex numbers and carrying out the calculations with the |L, S, L_{z}, S_{z}> basis, while generating the matrix containing the products of the matrix elements of the Stevens operators and the defined Stevens coefficients (B^{m}ₙ, O^{m}ₙ) and the component operators (x, y, z) of the external magnetic field, at first, an empty matrix is created with rows and columns numbered with |L_{z}, S_{z},> combinations, which, as the Hamiltonian matrix, is filled with components of the Stevens operators (B^{m}ₙ, O^{m}ₙ), the projection operators of total spin and the orbital magnetic moments, the component operators (x, y, z) of the external magnetic field and components of the spin-orbit coupling operators.

9. The optimisation of the method according to claim 7, wherein after filling with the products of the matrix elements of the Stevens operators and the defined Stevens coefficients (B^{m}ₙ, O^{m}ₙ), the projection operators of total spin and orbital magnetic moments, the component operators (x, z) or (x, y, z) of the external magnetic field and optionally with the components of the spin-orbit coupling operator, diagonalisation of the Hamiltonian matrix is carried out, and after the diagonalisation of the Hamiltonian matrix, n-complete sets of pairs of energy eigenvalues Eⁱ(i=1 . . . n) and eigenfunctions being linear combinations of basis vectors are calculated, and next, based on their form, the expected values of the directional components (x,z) or (x,y,z) of magnetic moments of individual n-eigenstates of energy Eⁱ are calculated.

10. The optimisation of the method according to claim 8, wherein after filling with the products of the matrix elements of the Stevens operators and the defined Stevens coefficients (B^{m}ₙ, O^{m}ₙ), the projection operators of total spin and the orbital magnetic moments, the component operators (x, z) or (x, y, z) of external the magnetic field and optionally with the components of the spin-orbit coupling operator, diagonalization of the Hamiltonian matrix is carried out, and after the diagonalization of the Hamiltonian matrix, n-complete sets of pairs of energy eigenvalues Eⁱ(i=1 . . . n) and eigenfunctions being linear combinations of basis vectors are calculated, and next, based on their form, the expected values of the directional components (x,z) or (x,y,z) of magnetic moments of individual n-eigenstates of energy Eⁱ are calculated.

11. The optimisation of the method according to claim 9, wherein n-eigenstates of energy Eⁱ are sorted with their expected values of directional components of magnetic moments <mⁱⱼ>(i=1 . . . n, j=x,z or j=x,y,z) of the individual states, and next, a sum of states Z(T) and population Nⁱ(T) of each energy state of an obtained structure are calculated in defined temperature increments according to Boltzmann statistics, based on which courses of temperature dependencies of free energy, internal energy, entropy, magnetic susceptibility, calculated for a field applied along (x and z) or (x, y and z) directions, and Schottky specific heat in order to determine calorimetric, electron and magnetic properties of a material containing ions in a defined environment of the crystal field (CEF) are calculated.

12. The optimisation of the method according to claim 10, wherein n-eigenstates of energy Eⁱ are sorted with their expected values of directional components of magnetic moments <mⁱⱼ>(i=1 . . . n, j=x,z or j=x,y,z) of the individual states, and next, a sum of states Z(T) and population Nⁱ(T) of every energy state of the obtained structure are calculated in defined temperature increments according to Boltzmann statistics, based on which courses of temperature dependencies of free energy, internal energy, entropy, magnetic susceptibility, calculated for a field applied along (x and z) or (x, y and z) directions, and Schottky specific heat in order to determine calorimetric, electron and magnetic properties of a material containing ions in a defined environment of the crystal field (CEF) are calculated.

13. The optimisation of the method according to claim 11, wherein a new complete set of result data is created, comprising the calorimetric, electron and magnetic properties of a material containing ions in the defined environment of the crystal field (CEF) together with an interactive visualisation of the environment and calculation parameters, and z new complete set of result data is presented in a form of an independent set of data available directly and in parallel with other result data, enabling direct comparisons of obtained results.

14. The optimisation of the method according to claim 12, wherein a new complete set of result data is created, comprising the calorimetric, electron and magnetic properties of a material containing ions in the defined environment of the crystal field (CEF) together with an interactive visualisation of this environment and calculation parameters, and the new complete set of result data is presented in a form of an independent set of data available directly and in parallel with other result data, enabling direct comparisons of obtained results.

15. The optimisation of the method according to claim 13, wherein various separate complete sets of the result data are archived in a single merged numerical form together with data pertaining to calculations, simulations and visualisations of every separate set of the result data, and the numerical form of the result data enables access to a chosen property or a course of a temperature dependency of a chosen property from different complete sets of the result data simultaneously.

16. The optimisation of the method according to claim 14, wherein various separate complete sets of the result data are archived in a single merged numerical form together with data pertaining to calculations, simulations and visualisations of every separate set of the result data, and the numerical form of the result data enables access to a chosen property or a course of a temperature dependency of a chosen property from different complete sets of the result data simultaneously.

17. The optimisation of the method according to claim 15, wherein a form of the result data enables implementation of the saved result data and comparison with adequate current calculations.

18. The optimisation of the method according to claim 16, wherein a form of the result data enables implementation of the saved result data and comparison with adequate current calculations.

19. A system for optimisation of a method for determining material properties when searching for materials having defined properties during which a chosen material containing ions of at least one element with unclosed electron shells is selected based on information available in the state of art, the system comprising a computing unit with a processor;
a device for presentation of data and calculation results and with access to data on materials and linked to the computing unit;
a testing unit carrying out tests on real materials and communicating with the computing unit wherein the processor comprises a module for finding and defining elements of the chosen material, enabling determination of their electron configuration based on values of quantum numbers of orbital magnetic moment L, spin magnetic moment S and optionally total magnetic moment J, and a module for finding a complete set of Crystal Electric Field (CEF) coefficients, defined by Stevens coefficients defining value of influence of electric multipoles interacting with an unclosed electronic subshell of ion and having a form of B^{m}ₙ, communicating with a module for construction of a model of an ideal material containing defined ions, the ions being spatially identically oriented and not interacting with one another but interacting with external fields, with a calculated structure of energy states together with their spectral properties, and being subjected to classical Boltzmann statistics, and having directional (x, y, z) or (x, z) components of magnetic properties calculated, the module for construction of a model of the ideal material being connected with the testing unit in order to verify the model of the ideal material with a real material in a module for comparison of the ideal material with the real material, when properties of the material obtained from calculations correspond to properties of the material being searched for.

20. The system for optimisation of the method according to claim 19, wherein the module for construction of the model of the ideal material comprises a module for calculation of complete sets of pairs of energy eigenvalues Eⁱ(i=1 . . . n) and eigenfunctions being linear combinations of basis vectors, and a module for calculation of courses of temperature dependencies of free energy, internal energy, entropy, magnetic susceptibility, calculated for a field applied along (x and z) or (x, y and z) directions, and Schottky specific heat in order to determine calorimetric, electron and magnetic properties of a material containing ions in defined environment of the crystal field (CEF).
